(19) United States
(12) Patent Application Publication
(10) Pub. No.: US 2021/0095373 A1
(43) Pub. Date: Apr. 1, 2021

(54) SYNTHETIC DIAMOND JEWELRY AND FABRICATION METHOD THEREOF

(71) Applicant: PT CREATIONS, Menlo Park, CA (US)

(72) Inventors: Parke G. BALLANTINE, Incline Village, NV (US); Arne W. BALLANTINE, Incline Village, NV (US); Neil Nabneet Singh LAMBA, Palo Alto, CA (US); Frank BALLANTINE, Palo Alto, CA (US); Suzanne SHARK, Palo Alto, CA (US); Trishal LAMBA, Palo Alto, CA (US)

(21) Appl. No.: 16/992,572

(22) Filed: Aug. 13, 2020

Related U.S. Application Data
(60) Provisional application No. 62/886,013, filed on Aug. 13, 2019.

(51) Int. Cl. C23C 16/27; B01D 53/04; B01D 53/32; C23C 16/56; C23C 16/52; C23C 16/44; G01M 3/04

(52) U.S. Cl. CPC C23C 16/27; B01D 53/0407; B01D 53/326; C23C 16/56; C23C 16/52; B01D 2256/16; G01M 3/04; B01D 2256/245; B01D 2257/102; B01D 2259/402; B01D 2253/116; C23C 16/4402

(57) ABSTRACT

A method of forming a diamond bulk object includes heating a crystalline material on a support disposed in a volume defined by a chamber, introducing into the volume a reactant gas including a hydrogen-containing component and a carbon-containing component, depositing a plurality of layers of diamond by chemical vapor deposition (CVD) to form at least a portion of the diamond bulk object on the support, and forming a predetermined color gradient in the plurality of layers of diamond.

### CROSS-REFERENCE TO RELATED APPLICATIONS

This application claims the benefit of U.S. Provisional Patent Application No. 62/886,013, filed on Aug. 13, 2019, the entire contents of which are incorporated herein by reference.

### FIELD

The present disclosure is directed to jewelry in general and to synthetic diamond and its method of fabrication.

### BACKGROUND

In case of prefabricated jewelry, a wearer's self-expression is limited to the choices made available by jewelry designers. While custom-made jewelry can provide a wearer with greater opportunity for self-expression, customization of jewelry is expensive. Further, whether prefabricated or customized, the structural configuration and appearance of a piece of jewelry is constrained by naturally occurring features of raw material used to create the piece and the original choices made by the designer at the time of fabrication of the piece. Accordingly, there remains a need for jewelry that can be cost-effectively customized across a variety of parameters to facilitate making a range of self-expression choices available to wearers of jewelry.

### SUMMARY

According to one aspect, a method of forming a diamond bulk object may include heating a crystalline material on a support disposed in a volume defined by a chamber, introducing into the volume a reactant gas including a hydrogen-containing component and a carbon-containing component, depositing a plurality of layers of diamond by chemical vapor deposition (CVD) to form at least a portion of the diamond bulk object on the support, and forming a predetermined color gradient in the plurality of layers of diamond.

According to another aspect, a synthetic diamond gem may include a diamond body, and a color gradient region having a different color from the diamond body and comprising at least one of a nitrogen or boron doped diamond region or a region in which the diamond crystal lattice is damaged by ionizing radiation.

According to yet another aspect, a method of leak testing a chemical vapor deposition (CVD) apparatus may include placing a dummy substrate in a chamber of the CVD apparatus, forming a vacuum environment in the chamber, providing an inert gas into the chamber and subjecting the dummy substrate to a predetermined thermal cycle in the chamber, detecting if a reaction product of air and a material of the dummy substrate is formed on the dummy substrate, and providing an alert indicative of a leak in the chamber based on detection of the reaction product on the dummy substrate.

According to still another aspect, a method of calibrating a temperature of a chemical vapor deposition (CVD) apparatus may include placing a dummy substrate in a chamber of the CVD apparatus, forming a vacuum environment in the chamber, providing a reactant into the chamber and subjecting the dummy substrate to a predetermined temperature in the chamber, forming a reaction product layer of the reactant and a material of the dummy substrate on the dummy substrate, determining a thickness of the reaction product layer, and determining if the temperature of the CVD apparatus is properly calibrated based on comparing the determined thickness of the reaction product layer to a stored thickness value for the predetermined temperature.

According to another aspect, a synthetic diamond gem may include first and second diamond fragments, wherein at least one of the first or second diamond fragments has a first color, and a synthetic diamond body of a second color different from the first color, epitaxially aligned to the first and second diamond fragments, such that the synthetic diamond body and the first and second diamond fragments form the synthetic diamond gem.

According to yet another aspect, a method of forming a diamond bulk object may include providing plurality of fragments of diamond in a chemical vapor deposition (CVD) chamber, wherein the fragments are spaced apart relative to one another to define one or more channels therebetween, and epitaxially growing by CVD a synthetic diamond body from exposed surfaces of the plurality of fragments along the one or more channels to join the plurality of fragments to one another to form the diamond bulk object.

According to still another aspect, a jewelry system may include at least one ornament, an attachment element coupled to at least one ornament, and a module comprising a light-emitting diode and battery, wherein the light-emitting diode is directed toward the at least one ornament.

According to yet another aspect, a modular jewelry system may include a plurality of ornaments, each ornament including a first fastening element and a second fastening element, the first fastening element of each ornament releasably engageable in tool-free securement with the second fastening element of each other ornament in two or more configurations, and an attachment element coupled to at least one of the plurality of ornaments, the attachment element and the plurality of ornaments collectively forming a wearable jewelry accessory releasably securable to a body of a wearer via tool-free securement of the attachment element to the first fastening element of each ornament, the second fastening element of each ornament, the body of the wearer, or a combination thereof.

According to still another aspect, a modular ring system may include a first section including at least one portion of a gallery and an ornament disposed along the at least one portion of the gallery, and a second section including at least a portion of a band, and the first section and the second section releasably engageable with one another to collectively form a ring including the band and the gallery, the band having an inner surface and an outer surface opposite the inner surface, the inner surface of the band configured to circumscribe a digit of a wearer of the ring, and the ornament disposed along the gallery at least partially exposed in a direction away from the outer surface of the band with the inner surface of the band circumscribed about the finger of the wearer.

### BRIEF DESCRIPTION OF THE FIGURES

FIG. 1A is a schematic representation of a system for forming a bulk object, the system including a chemical vapor deposition (CVD) reactor for synthesizing crystalline material, the CVD reactor shown at a first time prior to synthesis of a layer of the crystalline material.

FIG. 1B is a schematic representation of the system of FIG. 1A shown at a second time during synthesis of the layer of the crystalline material.

FIG. 1C is a schematic representation of the system of FIG. 1A shown at a third time following synthesis of a plurality of layers of the crystalline material forming at least a portion of a bulk object.

FIG. 2 is a flowchart of an exemplary method of synthesizing a plurality of layers of crystalline material forming at least a portion of a bulk object.

FIG. 3A is a top view of the plurality of layers of crystalline material of the bulk object of FIG. 1C, with a predetermined color gradient along the plurality of layers of crystalline material.

FIG. 3B is a side view of a cross-section of the plurality of layers of crystalline material along the section 3B-3B in FIG. 3A, with getter disposed along a surface of the plurality of layers of crystalline material having a predetermined color gradient.

FIG. 4A is a schematic representation of a processing station for imparting the predetermined color gradient of FIG. 1C to the plurality of layers of crystalline material of the bulk object of FIG. 1C.

FIG. 4B is a perspective view of a collimator of the processing station of FIG. 4A.

FIG. 5A is a top view of a plurality of layers of crystalline material of a bulk object exposed to radiation to form a predetermined pattern corresponding to a pattern augmenting a facet pattern

FIG. 5B is a top view of a plurality of layers of crystalline material of a bulk object exposed to radiation to form a predetermined pattern corresponding to a cat's eye pattern.

FIG. 5C is a top view of a plurality of layers of crystalline material of a bulk object exposed to radiation to form a predetermined pattern corresponding to a flower pattern.

FIG. 5D is a top view of a plurality of layers of crystalline material of a bulk object exposed to radiation to form a predetermined pattern corresponding to a cross pattern.

FIG. 5E is a top view of a plurality of layers of crystalline material of a bulk object exposed to radiation to form a predetermined pattern corresponding to a shading effect.

FIG. 6 is a schematic representation of a first gas source for use in an intake system of the system of FIG. 1A to introduce methane as a precursor gas into the CVD reactor.

FIG. 7 is a schematic representation of an intake system for use with the system of FIG. 1A to introduce hydrogen and methane into the CVD reactor as a precursor gas.

FIG. 8 is a flowchart of an exemplary method of detecting shifts in chemical vapor deposition conditions for synthesis of crystalline material.

FIG. 9 is a side view of a thickness of a reactant product on a dummy substrate in the system of FIG. 1A in the presence of a fixed volumetric flow of a reactant.

FIG. 10 is a flowchart of an exemplary method of forming a bulk object.

FIG. 11A is a top view of a fixture supporting a plurality of fragments of a single-crystal material and positionable in the CVD reactor of FIG. 1A to join the plurality of fragments to one another.

FIG. 11B is a side view between two fragments corresponding to the area of detail 11B in FIG. 11A.

FIG. 11C is a top view of a bulk object formed from chemical vapor deposition of a single-crystal material between the plurality of fragments in the fixture of FIG. 11A.

FIG. 11D is a side view of the bulk object formed from chemical vapor deposition of a single-crystal material between the plurality of fragments in the fixture of FIG. 11B.

FIG. 12A is a top view of a collection of parts of a modular jewelry system, the collection of parts unconnected to one another.

FIG. 12B is a top view of the modular jewelry system of FIG. 12A in a first configuration of a wearable jewelry accessory.

FIG. 12C is a top view of the modular jewelry system of FIG. 12A in a second configuration of a wearable jewelry accessory.

FIG. 12D is a top view of the modular jewelry system of FIG. 12A in a third configuration of a wearable jewelry accessory.

FIG. 13A is a top view of an ornament including a portion defining a setting, with the portion shown in a first position to receive a stone.

FIG. 13B is a top view of the ornament of FIG. 13A, with the portion shown in a second position overlapping the stone in the setting.

FIG. 14A is a side view of a collection of parts of a modular ring system, the collection of parts unconnected to one another.

FIG. 14B is a side view of the modular ring system of FIG. 14A in a configuration of a ring.

FIG. 15 is a schematic representation of an ornament including a power source and a motion element.

FIG. 16 is a schematic representation of a system including a power source and a light-emitting diode carried along an ornament.

FIG. 17 is a photograph of fluorescence of a pink sapphire lit by the light-emitting diode of the ornament of FIG. 16 emitting long-wave ultraviolet light.

FIG. 18A is a graphical representation of a duty-cycle of predetermined step changes in on/off states associated with blinking the light-emitting diode of the ornament of FIG. 16.

FIG. 18B is a graphical representation of a duty-cycle of predetermined step changes in on/off states including fast pulses and long periods of off time of the light-emitting diode of the ornament FIG. 16.

FIG. 18C is a graphical representation of a duty-cycle of predetermined step-changes between red and green states of the light-emitting diode of the ornament of FIG. 16.

FIG. 18D is a graphical representation of a duty-cycle of a predetermined sinusoidal variation of on/off states of the light-emitting diode of the ornament of FIG. 16.

FIG. 18E is a graphical representation of a duty-cycle of on/off state of the light-emitting diode of the ornament of FIG. 16 based on pulses of sound measured by a sensor of the ornament of FIG. 16.

FIG. 19 is an exploded side view of a system including an ornament securable into contact with a gem.

FIG. 20A is a side view of a system arranged as an earring and including a light-emitting diode, with the earring shown secured to an ear of a wearer via a piercing.

FIG. 20B is a front view of a battery of the system of FIG. 20A.

FIG. 21 is a perspective view of a modular ring system in the shape of a ring and including a light-emitting diode.

FIG. 22 is a perspective view of a modular ring system in the shape of a ring and including a light pipe.

FIG. 23 is a schematic representation of a security system including a jewelry piece, an RFID tag having an antenna circuit, and a storage box including a shorting element for the antenna circuit.

Like reference symbols in the various drawings indicate like elements.

### DETAILED DESCRIPTION

The embodiments will now be described more fully hereinafter with reference to the accompanying figures, in which exemplary embodiments are shown. The foregoing may, however, be embodied in many different forms and should not be construed as limited to the exemplary embodiments set forth herein.

All documents mentioned herein are hereby incorporated by reference in their entirety. References to items in the singular should be understood to include items in the plural, and vice versa, unless explicitly stated otherwise or clear from the text. Grammatical conjunctions are intended to express any and all disjunctive and conjunctive combinations of conjoined clauses, sentences, words, and the like, unless otherwise stated or clear from the context. Thus, the term “or” should generally be understood to mean “and/or,” and the term “and” should generally be understood to mean “and/or.”

Recitation of ranges of values herein are not intended to be limiting, referring instead individually to any and all values falling within the range, unless otherwise indicated herein, and each separate value within such a range is incorporated into the specification as if it were individually recited herein. The words “about,” “approximately,” or the like, when accompanying a numerical value, are to be construed as including any deviation as would be appreciated by one of ordinary skill in the art to operate satisfactorily for an intended purpose. Ranges of values and/or numeric values are provided herein as examples only, and do not constitute a limitation on the scope of the described embodiments. The use of any and all examples or exemplary language (“e.g.,” “such as,” or the like) is intended merely to better illuminate the embodiments and does not pose a limitation on the scope of those embodiments. No language in the specification should be construed as indicating any unclaimed element as essential to the practice of the disclosed embodiments.

As used herein, the term “gas” or variants thereof (e.g., precursor gas or reactant gas) shall be understood to be understood to include a single-component gas or a multi-component gaseous mixture, unless otherwise specified or made clear from the context. This convention is used herein for the sake of efficient and clear explanation, and shall not be understood to limit any aspects of the present disclosure. Thus, for example, a gas may include hydrogen alone, or in a mixture with methane.

In the description that follows, the terms “precursor gas” and “reactant gas” shall be generally understood to delineate between a first gas (the “precursor gas”) that has a stable composition as it moves in the system and a second gas (the “reactant gas”) that includes a hydrogen-containing component and a carbon-containing component suitable for synthesis into crystalline material under conditions associated with chemical vapor deposition. Thus, according to the convention used herein, a reactant gas may be understood to be introduced into a volume by delivering energy to a precursor gas to form the reactant gas. However, while the use of a precursor gas is described herein, it shall be appreciated that this is for the sake of setting forth certain aspects of techniques described herein. It shall be further appreciated, therefore, that the reactant gas may be formed outside of a volume such that the reactant gas may be understood to be introduced into the volume by flowing the reactant gas into the volume.

As also used herein, the term “predetermined color gradient” shall be understood to include any variation in color imparted to a crystalline material according to one or more design criteria set forth in advance of synthesis of the crystalline material according to any one or more of the various different techniques set forth herein. Thus, unless otherwise specified or made clear from the context, a predetermined color gradient shall be understood to include any one or more of the following: a continuous variation in color along a portion of a crystalline material; a step change in color variation between two adjacent portions of a crystalline material; shading along a portion of a crystalline material; a geometric pattern imparted to a crystalline material; or indicia imparted to crystalline material.

Further, as used herein, the term “vacuum environment” shall be understood to refer to a pressure in a given volume of less than atmospheric pressure outside of the given volume, unless otherwise specified or made clear from the context. Thus, for example, in instances in which the atmosphere outside of the given volume is ambient pressure (e.g., about one atmosphere), a reference to a vacuum environment shall be understood to refer to a pressure of less than about one atmosphere in the given volume. Additionally, or alternatively, the presence of a vacuum environment shall be understood to draw gas into the given volume from a region of higher gas pressure, which may be an intentional source of higher-pressure gas (e.g., through a defined orifice) and/or an unintentional source of higher-pressure gas (e.g., through leaks in the system).

Additionally, or alternatively, as used herein the term “synthesis” and variants thereof, shall be understood include any one or more of various different types of growth or deposition in which a crystalline material is formed on a substrate through chemical vapor deposition. Accordingly, unless otherwise specified or made clear in a given context, synthesis is intended to include any form of epitaxial growth of crystalline material (e.g., homoepitaxy or heteroepitaxy).

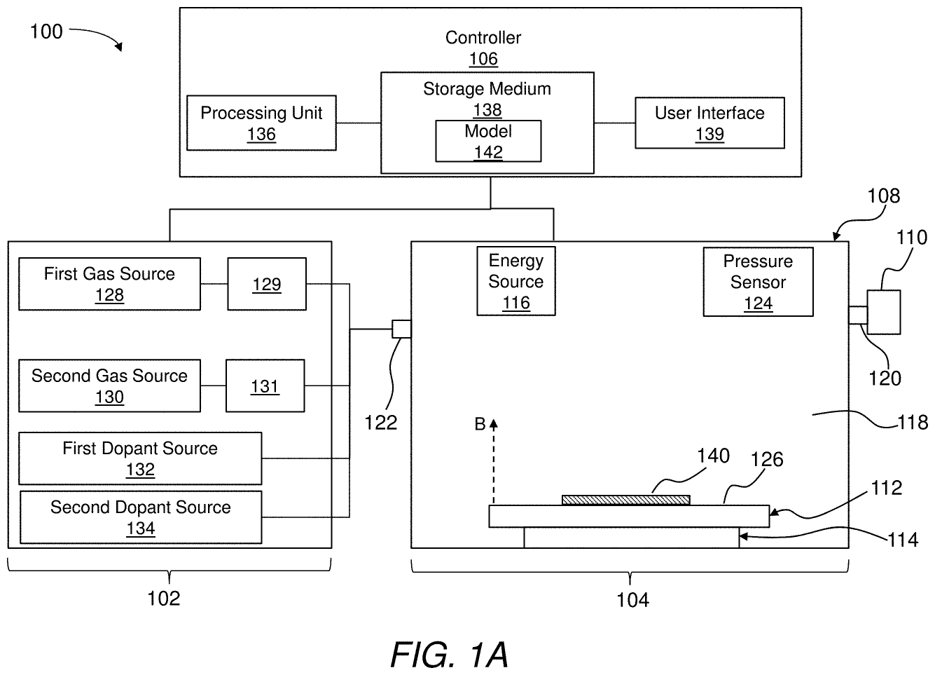

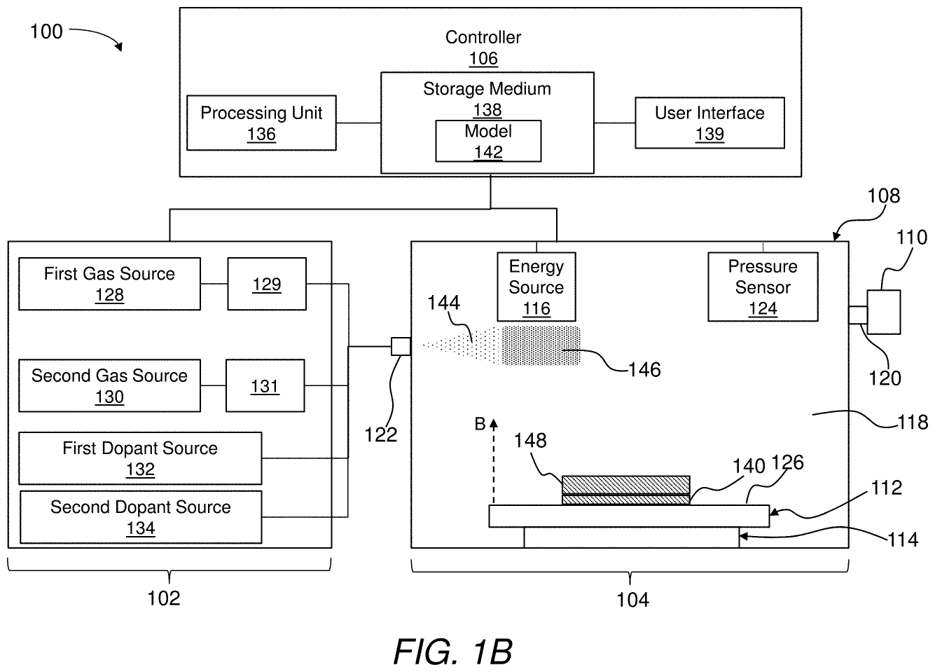

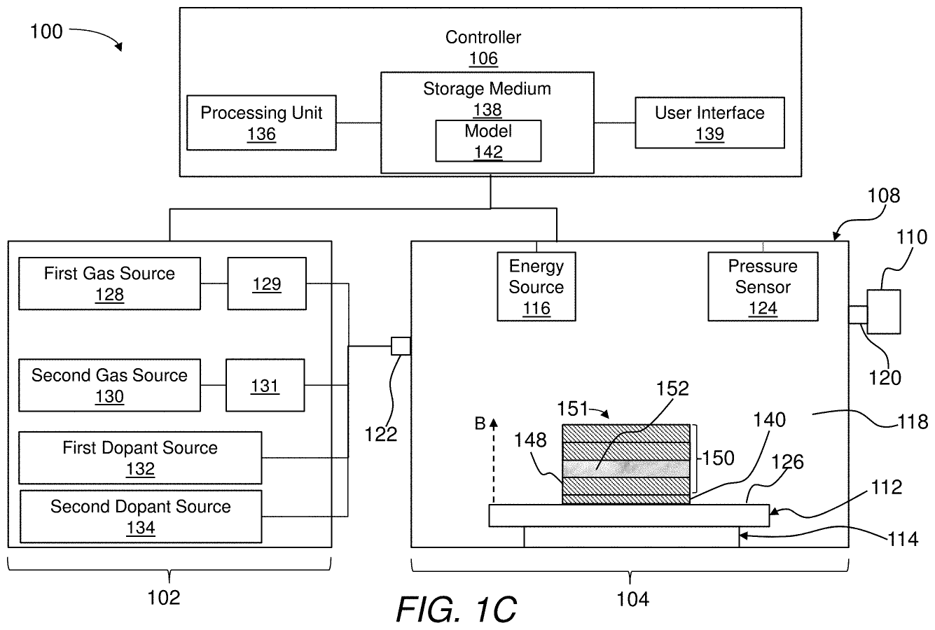

Referring now to FIG. 1A, a system 100 for forming a bulk object may include an intake system 102, a chemical vapor deposition (CVD) reactor 104, and a controller 106. The CVD reactor 104 may include, for example, a chamber 108, a vacuum source 110, a support (e.g., a susceptor or other support for synthesis of a crystalline material thereon) 112, a heater 114, and an energy source 116. Generally, the chamber 108 may define a volume 118, and the chamber 108 may further, or instead, support one or more of the vacuum source 110, the support, 112, the heater 114, and the energy source 116 relative to the volume 118. In use, as described in greater detail below, the controller 106 may control one or more of the intake system 102, the vacuum source 110, the heater 114, and the energy source 116 in coordination with one another to form an environment within the volume 118 defined by the chamber 108 that promotes synthesis of a crystalline material (e.g., diamond) on the support 112 while imparting a predetermined color gradient to the crystalline material synthesized on the support 112. Accordingly, as also described in greater detail below, the system 100 may advantageously facilitate achieving a repeatable and wide-range of variations in the appearance of crystalline materials, as compared to the unpredictable and limited variations in appearance of crystalline materials extracted from natural deposits. Thus, in turn, the controllable appearance of the crystalline material formed by the system 100 may facilitate fabrication of jewelry pieces according to predetermined color gradients that are otherwise difficult—if not impossible—to achieve using only naturally occurring crystalline materials.

In general, the vacuum source 110 may be in fluid communication with the volume 118 of the chamber 108 via an exhaust port 120 defined by the chamber 108, and the intake system 102 may be in fluid communication with an inlet port 122 defined by the chamber 108. In this configuration, the vacuum source 110 may be any of various different types of vacuum pumps, such as cryopumps, regenerative pumps, positive displacement pumps or momentum transfer pumps, suitable for creating a vacuum and moving gaseous contents through the volume 118 in a direction defined generally from the inlet port 122 to the exhaust port 120, drawing a gas from the intake system 102 through the volume 118 and, ultimately, exhausting contents of the volume 118 through the exhaust port 120. While the vacuum source 110 may exhaust to an atmosphere outside of the system 100, at least some of the exhaust may be recirculated in certain instances, as described in greater detail below.

In certain instances, the system 100 may include an optional pressure sensor 124 in fluid communication with the volume 118 and in electrical communication with the controller 106. Continuing with this example, the pressure sensor 124 may send a signal indicative of pressure in the volume 118 to the controller 106. Based at least in part on the signal from the pressure sensor 124, the controller 106 may adjust the vacuum source 110 to maintain substantially a target vacuum pressure in the volume 118, such as may be achieved through any one or more of various feedback techniques.

The support 112 may be disposed in the volume 118 between the inlet port 122 and the exhaust port 120 such that gaseous contents in the volume 118 may move over the support 112 and any material carried on the support 112 as part of any one or more of the processes described herein. In certain instances, the support 112 may be any material that remains inert with respect to contents of the volume 118 under the elevated temperatures and low pressures, within the volume 118, as chemical vapor deposition is carried out in the volume 118 to form a crystalline material. Further, or instead, the support 112 may have a build surface 126 that is substantially two-dimensional in a plane perpendicular to a build direction “B” of the crystalline material. That is, as two-dimensional layers of crystalline material are built on top of each other in the build direction “B”, the bulk object takes on a three-dimensional form. Thus, for example, the build surface 126 may be generally sized to accommodate a predetermined dimensions two-dimensional footprint of the bulk object being formed in the volume 118. Additionally, or alternatively, the support 112 may include a thermally conductive material at least along the build surface 126 to facilitate efficient heat transfer to crystalline material disposed along the build surface 126 and/or above the build surface 126 in the build direction. Thus, by way of example and not limitation, the support 112 may be a metal susceptor or another support which supports a seed material 140 (e.g., high pressure high temperature (HPHT) diamond plate or crushed diamond) used to nucleate CVD diamond thereon.

The heater 114 may be any one or more of various different heat sources controllable to transfer sufficient heat into the volume 118 to maintain a temperature or a range of temperatures (e.g., greater than about 600° C. and less than about 1000° C., such as about 700 to 900° C.) in the volume 118 as gaseous contents move through the volume 118, from the inlet port 122 to the exhaust port 120 under vacuum pressure imparted to the volume 118 by the vacuum source 110. In some instances, the heater 114 may be in thermal communication with the support 112 via a thermally conductive path between the heater 114 and the support, via convection through the gaseous contents in the volume 118, or a combination thereof. Further, or instead, the heater 114 may be controllable through any one or more of various different temperature cycles suitable for promoting layer-by-layer synthesis of crystalline material, such as ramping up to a target temperature, holding temperature at about the target temperature to facilitate synthesis of a layer of crystalline material, and ramping down to a base temperature to interrupt synthesis of crystalline material on the support 112. As an example, the heater 114 may be an RF induction heater containing an RF induction coil or a resistance including one or more resistors.

In some implementations, energy from the energy source 116 may be imparted to a precursor gas to facilitate formation of a reactant gas including radicals useful for synthesis of the crystalline material on the support 112. Given the reactivity of radicals, the energy source 116 may be usefully positioned relative to one or more other components of the system 100 to deliver energy to the precursor gas in the vicinity of the support 112 to increase the likelihood that radicals formed by the energy from the energy source 116 reach an intended target area on the support 112. As an example, the energy source 116 may be positioned to deliver energy to a precursor gas in one or more of the intake system 102, the volume 118, or a combination thereof such that an appropriate reactant gas is introduced into the volume 118. For example, in the context of synthesizing diamond on the support 112, the energy delivered from the energy source 116 may form a gas that is carbon-rich and has a high concentration of one or more components (e.g., atomic hydrogen) that suppress the formation of graphitic carbon bonds and etches the non-diamond carbon deposits from the support 112.

The energy source 116 may be any one or more of various different types of energy sources controllable to deliver energy into a precursor gas to introduce an appropriate reactant gas in the volume 118 in the vicinity of the support 112. As an example, the energy source 116 may include a thermal energy source (e.g., a hot filament or a combustion flame) or a plasma source, such as one or more of a radiofrequency (RF) power source or a microwave power source controllable to break chemical bonds of one or more components in the precursor gas to form suitable radicals in the reactant gas. In some instances, the energy source 116 may form at least a portion of the precursor gas into plasma. Thus, for the sake of clear and efficient description, the term “reactant gas” may include plasma unless otherwise indicated or made clear from the context.

In general, the intake system 102 may include a plurality of gas sources to deliver a precursor gas to the volume 118 according to a predetermined target concentration of constituents of the precursor gas. In particular, the intake system 102 may be controllable to deliver a gas having a carbon-to-hydrogen ratio (or some other useful indicator of hydrogen-containing components and carbon-containing components) substantially equal to a predetermined target value (e.g., within ±2 percent of the predetermined target value). Additionally, or alternatively, the intake system 102 may be controllable to deliver one or more dopants into the volume 118 in a concentration substantially equal to a predetermined target value (e.g., within ±2 percent of the predetermined target value) to impart a predetermined color gradient to the plurality of layers of crystalline material formed on the support 112.

As an example, the intake system 102 may include a first gas source 128, a second gas source 130, a first dopant source 132, and a second dopant source 134. Each one of the first gas source 128, the second gas source 130, the first dopant source 132, or the second dopant source 134 may be a gas storage cylinder or other container of the respective gas composition being introduced. This may be useful, for example, for sourcing each respective gas according to specific purity levels to reduce the likelihood of introducing contaminants into the volume 118.

The first gas source 128 and the second gas source 130 may be independently controllable relative to one another via electrical communication between the controller 106 and the first gas source 128, the second gas source 130, or a combination thereof. As may be appreciated, such independent control may facilitate substantially achieving the predetermined target value indicative of hydrogen-containing components and carbon-containing components in the precursor gas delivered from the intake system 102 to the volume 118. In certain implementations, the first gas source 128 may include atomic hydrogen (H₂) and the second gas source 130 may include methane (CH₄). Additionally, or alternatively, the first dopant source 132 and the second dopant source 134 may be independently controllable relative to one another and relative to one or more of the first gas source 128 and the second gas source 130 via electrical communication between the controller 106 and each of the first dopant source 132 and the second dopant source 134. Accordingly, in certain implementations, the first dopant source 132 may be controlled to achieve a predetermined concentration of the first dopant in a given layer of crystalline material, and the second dopant source 134 may be controlled to achieve a predetermined concentration of the second dopant in the given layer or another layer of the crystalline material such that controlled introduction of one or both of first dopant or the second dopant into the volume 118 introduces a predetermined color gradient into the plurality of layers of crystalline material formed on the support 112. As an example, the first dopant source 132 may include a nitrogen-containing gas (e.g., elemental nitrogen or ammonia), and the second dopant source 134 may include a boron-containing gas (e.g., diborane). Continuing with this example, in some instances, small amounts of the boron-containing gas (e.g., diborane) from the second dopant source 134 may be delivered to the volume 118 to create a slight blue color in the deposited CVD diamond to offset a yellow color associated with nitrogen contamination. Alternatively or in addition, small amounts of the nitrogen-containing gas from the first dopant source 132 may be delivered to the volume 118 to create a yellow blue color in the deposited CVD diamond. While two dopant sources are shown, it should be appreciated that this is for the purpose of providing an example useful for explaining certain aspects of doping and, unless otherwise specified or made clear from the context, less than two doping sources may be used in some instances and greater than two doping sources may be used in other instances.

In certain implementations, the intake system 102 may additionally or alternatively optionally include a first purifier 129 and a second purifier 131. While the first gas source 128 and the second gas source 130 may be sourced to meet certain purity levels, it shall be appreciated that such purity levels may vary and/or may be difficult to source from vendors. Accordingly, the first purifier 129 may be in-line with the first gas source 128 and upstream of the inlet port 122 of the chamber 108 such that the first gas moving from the first gas source 128 passes through the first purifier 129 prior to entering the volume 118. In an analogous orientation, the second purifier 131 may be in-line with the second gas source 130 and upstream of the inlet port 122 of the chamber 108 such that the second gas moving from the second gas source 130 passes through the second purifier 131 prior to entering the volume 118. Thus, in general, the first purifier 129 and the second purifier 131 may reduce the likelihood of inadvertently introducing contaminants (e.g., trace gases with nitrogen-containing components) into the volume 118 and, in turn, facilitate achieving more accurate control over the chemical vapor deposition process carried out in the volume 118. It shall be understood that the first purifier 129 and the second purifier 131 may be any one or more of various different types of purifiers useful for purification of the respective gas passing through each purifier. Thus, by way of example and not limitation, the first purifier 129 and the second purifier 131 may each include one or more of a palladium membrane, a palladium-copper membrane, a molecular sieve (e.g., zeolite, activated carbon, nanoporous glass, etc.), a pressure-swing adsorber, or a temperature swing adsorber. In the gas in which the gas from the first gas source 128 or the second gas source 130 is hydrogen, a respective one of the first purifier 129 or the second purifier 131 may be an electrochemical pump, such as a proton exchange membrane (PEM) pump which pumps hydrogen from one side of the membrane to the opposite side of the membrane under an applied voltage or current, without pumping of impurities such as nitrogen through the membrane.

In some implementations, waste gas from the first purifier 129 may be recirculated to pass through the first purifier 129 again or through a different purifier, as may be useful to reduce the amount of waste associated with a given configuration of purifiers. Analogous recirculation of waste gas from the second purifiers 131 may, additionally or alternatively, be used to reduce waste gas associated with purification associated with the second gas. An example of such recirculation to reduce waste gas is described in greater detail below with respect to a double-loop purification system to form a purified methane stream.

In general, the controller 106 may include a processing unit 136 and a computer-readable storage medium 138 having stored thereon instructions for causing the processing unit 136 to carry out one or more aspects of any of the various different techniques described herein for forming crystalline material, such as diamond, and imparting a predetermined color gradient to the crystalline material. Additionally, or alternatively, the controller 106 may include a user interface 139 through which a user may provide inputs to the system 100 (e.g., via a keyboard, a mouse, a touchscreen, etc.) and may receive alerts from the system 100 (e.g., via indicia on a screen, an alarm sound, etc.).

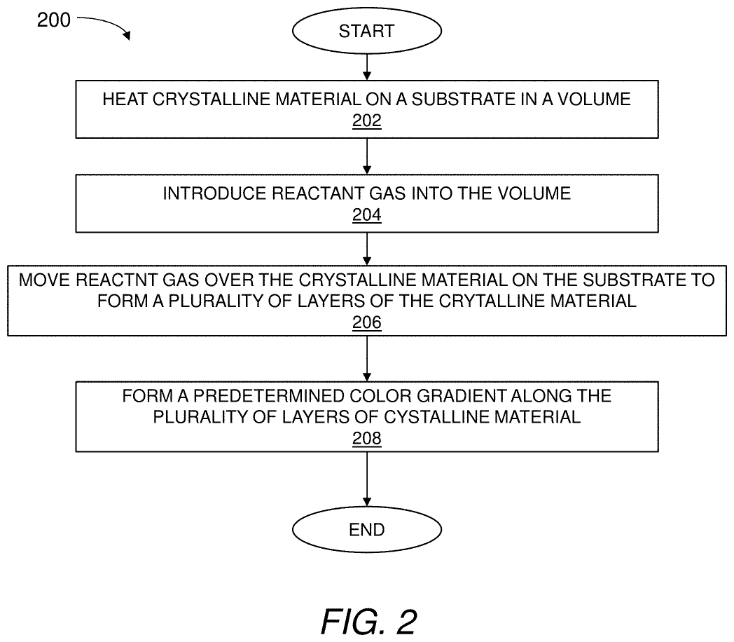

FIG. 2 is a flowchart of an exemplary method 200 of synthesizing a plurality of layers of crystalline material forming at least a portion of a bulk object. Unless otherwise specified or made clear from the context, the exemplary method 200 may be implemented using any one or more of the various different systems, and components thereof, described herein. Thus, for example, the exemplary method 200 may be implemented as computer-readable instructions stored on the computer-readable storage medium 138 (FIG. 1A) and executable by the processing unit 136 (FIGS. 1A-1C) of the controller 106 (FIG. 1A) to operate the system 100 (FIG. 1A).

As shown in step 202, the exemplary method 200 may include heating a crystalline material on a support disposed in a volume defined by a chamber. In general, the crystalline material may be heated on the support according to any one or more of the various different techniques described herein. For example, heating the crystalline material may include any one or more of various different combinations of induction, conduction or convection heating of a crystalline seed material (e.g., a HPHT diamond plate) 140 located on a support (e.g., a susceptor) 112 to a temperature greater than about 600° C. and less than about 1000° C., such as about 700 to 900° C. Further, or instead, heating the crystalline material on the support may include any one or more of various different thermal cycles, including such cycles having a high-temperature portion for promoting deposition of material on the crystalline material and lower-temperature portion for annealing the deposited material. Further, as used in this context, it shall be appreciated that the crystalline material heated on the support may initially include a seed material (e.g., a material placed on the support and having the same crystalline structure as the material to be synthesized on the support) and, with respect to layers deposited after the initial layer, the crystalline material may include crystalline material synthesized in previous layers.

As shown in step 204, the exemplary method 200 may include introducing into the volume 118 a reactant gas including a hydrogen-containing component and a carbon-containing component from the sources 128 and 130. Unless otherwise specified or made clear from the context, introduction of such a reactant gas into the volume may include any one or more techniques described herein for forming a reactant gas from a precursor gas and/or delivering the reactant gas from an intake system to the volume. Thus, in general, introducing the reactant gas into the volume may include any one or more of various different techniques described herein for increasing concentration in the volume of at least one of the hydrogen-containing component or the carbon-containing component. In some implementations, introducing the reactant gas into the volume may include purifying a precursor gas. Examples of purifying a precursor gas to form the reactant gas may include moving the precursor gas through one or more purifiers 129, 131 as described above.

As shown in step 206, the exemplary method 200 may include moving the reactant gas over the crystalline material heated on the support. In general, movement of the reactant gas over the crystalline material may synthesize a plurality of layers of crystalline material (e.g., diamond) forming at least a portion of a bulk object on the support. The movement of the reactant gas over the crystalline material may be at least partially achieved using vacuum pressure in the volume. Further, or instead, movement of the reactant gas over the crystalline material heated on the support may be modulated (e.g., in coordination with a thermal cycle) to facilitate layer-by-layer synthesis of the plurality of layers of crystalline material.

As shown in step 208, the exemplary method 200 may include forming a predetermined color gradient along the plurality of layers of crystalline material, such as diamond. The predetermined color gradient may be any one or more of the various different predetermined color gradients described herein. Accordingly, unless otherwise indicated or made clear from the context, it shall be understood that forming the predetermined color gradient along the plurality of layers of crystalline material may be carried out according to any one or more of the various different techniques described herein for imparting a predetermined color gradient to the plurality of layers. For example, forming the predetermined color gradient may include selectively varying a concentration of one or more dopants in the reactant gas according to a predetermined profile as the plurality of layers of crystalline material synthesize to form at least a portion of a bulk object. As more specific examples, the or more dopants may be introduced into the plurality of layers via gas moved from an intake system to in-situ dope one or more layers of crystalline material (e.g., CVD diamond layers) during deposition, and/or as described in greater detail below, through ion implantation of dopant ions into the plurality of layers of crystalline material. Additionally, or alternatively, forming the predetermined color gradient in the crystalline material may include irradiating the plurality of layers of crystalline material with ionizing radiation to one or more depths, as also described in greater detail below.

In certain instances, the predetermined color gradient along the plurality of layers of crystalline material may be associated with variations of properties, in addition to color, along the plurality of layers. For example, a dopant may be selectively introduced into the plurality of layers of crystalline material to form an interlayer variation in concentration of the dopant in the plurality of layers of crystalline material, and the interlayer variation in concentration may result in a predetermined color gradient as well as a predetermined variation in one or more other physical properties between the layers. As a more specific example, the interlayer variation in concentration of the dopant in instances in which the dopant is nitrogen may form stress relief between two adjacent layers in the plurality of layers. That is, a first layer may have a low concentration of nitrogen or no nitrogen at all, and a second layer may have a higher concentration of nitrogen than found in the first layer and the resulting difference in nitrogen concentration may form a color gradient as well as stress relief between the two layers.

FIGS. 1A-1C illustrate a series of steps that may be carried out by the system 100 according to one or more aspects of the exemplary method 200 (FIG. 2) to synthesize a plurality of layers of crystalline material and impart a predetermined color gradient to such layers to facilitate jewelry fabrication beyond conventional constraints associated with designing jewelry using naturally-occurring gems.

Referring now to FIG. 1A, at a first time prior to synthesis of a crystalline material, one or more of various different aspects of the system 100 may be prepared for carrying out chemical vapor deposition according to controlled conditions suitable for forming a bulk object having a predetermined color gradient. As an example, since the support 112 typically has a composition different from the crystalline material to be formed (e.g., the susceptor is typically not formed from diamond in a CVD diamond system 100), a seed material 140 may be arranged on the build surface 126 of the support 112. As a more specific example, in instances in which the crystalline material to be formed is diamond, the seed material 140 may be a HPHT diamond plate and/or crushed diamond. More generally, the seed material 140 may be compatible with the crystalline material to be formed to facilitate synthesis (e.g., homoepitaxial growth) of a first layer of the crystalline material (e.g., CVD diamond) on the build surface 126.

Additionally, or alternatively, in the initial phase, a model 142 may be stored on the computer-readable storage medium 138. The model 142 may include various different aspects of the bulk object to be formed. As an example, information stored in the model 142 may include doping levels to be delivered from the first dopant source 132 and/or the second dopant source 134 to each layer of crystalline material to impart a predetermined color gradient to a plurality of layers of the crystalline material. In certain instances, information stored in the model 142 may include one or more of various different target geometric parameters (e.g., thickness) of the plurality of layers of crystalline material to be formed, target gas flow rates of the first gas source and/or the second gas source, or target temperature and pressure conditions in the volume 118 as a layer-by-layer process of chemical vapor deposition is carried out in the volume 118 to synthesize a plurality of layers of crystalline material in a layer-by-layer process.

Referring now to FIG. 1B, at a second time during synthesis of a layer of the crystalline material, the heater 114 may direct heat to a crystalline material on the build surface 126 of the support 112. That is, in the case of formation of a first layer as shown, the heater 114 may direct heat to the seed material 140 on the build surface 126 of the support 112. For a second and subsequent layers, the heater 114 may direct heat to each preceding layer and the seed material 140 on the build surface 126.

The intake system 102 may deliver a precursor gas 144 to the volume 118. The precursor gas 144 may be, for example, a multi-component gas formed from a mixture of a first gas from the first gas source 128 and a second gas from the second gas source 130, such as a mixture of hydrogen gas and methane containing 0.1% to 8% by volume methane, such as 0.2% to 1% by volume methane. The precursor gas 144 may, further or instead, include one or more of a first dopant from the first dopant source 132 or a second dopant from the second dopant source 134 according to a predetermined doping profile specified in the model 142 stored on the computer-readable storage medium 138.

The energy source 116 may direct energy (e.g., thermal energy, RF energy, microwave energy, or a combination thereof) into the precursor gas 144 to change one or more components of the precursor gas 144. That is, based at least in part on the energy delivered from the energy source 116 to the precursor gas 144, a reactant gas 146 is introduced into the volume 118. In general, the reactant gas 146 may form an environment above the build surface 126 of the support 112 to facilitate synthesis of a layer of crystalline material. As an example, in instances in which the crystalline material is diamond, the environment provided by the reactant gas 146 above the build surface 126 of the support 112 is a high supersaturation of atomic hydrogen and hydrocarbon radicals. More generally, at the elevated temperature and vacuum pressure in the volume 118, at least a portion of the reactant gas 146 may form a first layer 148 on the seed material 140 disposed on the build surface 126 of the support 112. The first layer 148 may comprise an undoped CVD diamond layer, a boron doped CVD diamond layer, a nitrogen doped CVD diamond layer and/or a boron and nitrogen doped CVD diamond layer.

As the first layer 148 is formed on the seed material 140, the system 100 may prepare for formation of subsequent layers. For example, through operation of the vacuum source 110, any excess amount of the reactant gas 146 may be removed from the volume 118 via the exhaust port 120. As shall be appreciated, this may be useful for controlling doping levels in the reactant gas 146 according to variations associated with imparting a predetermined color gradient along a plurality of layers of synthesized crystalline material. Additionally, or alternatively, the temperature in the volume 118 may be ramped down to strengthen the first layer 148 through, for example, annealing. Following such steps to reset the system 100, in general, the process described above with respect to formation of the first layer 148 may be repeated as many times as necessary according to the specifications of the model 142 to form a plurality of layers, such as a plurality of doped and/or undoped CVD diamond layers 150.

Thus, referring now to FIG. 1C, at a third time following synthesis of a plurality of layers 150 of the crystalline material may form at least a portion of a bulk object 151 on the support 112. It shall be appreciated that each layer in the plurality of layers 150 may be deposited according to a layer-by-layer process, with each layer deposited according to one or more parameters specified in the model 142 stored on the computer-readable storage medium 138. Accordingly, the plurality of layers 150 shall be generally understood to have an overall appearance corresponding substantially to a predetermined overall appearance corresponding to the model 142, with allowances for deviations associated with variations in one or more process parameters as the layer-by-layer process is carried out. For example, through control of concentration of one or more dopants delivered from the first dopant source 132 and the second dopant source 134 according to the specifications of the model 142 stored on the computer-readable storage medium 138, the plurality of layers 150 may exhibit a predetermined color gradient 152 and, thus, a predetermined appearance that may be useful for cost-effective and repeatable fabrication of complex jewelry pieces.

In one embodiment, each of the plurality of layers 150 may include a different dopant concentration or no dopant by selectively activating and deactivating the doped sources 132 and/or 134. Thus, a color gradient region 152 (e.g., a region having a different color than the other regions of the object (e.g., CVD diamond gem) 151) may be formed in-situ during the deposition of the plurality of layers 150. For example, one or more diamond layers 148 of the plurality of layers 150 may be doped with boron to appear bluer than the remaining clear undoped layers, while another one or more layers 148 of the plurality of layers 150 may be doped with nitrogen to appear more yellow than the remaining undoped clear layers. Thus, a blue and/or yellow pattern may be formed in the CVD diamond bulk object (e.g., gem) 151.

In another embodiment, different layers 148 of the plurality of layers 150 have a different concentration of nitrogen dopant to relieve stress in the gem 151. For example, alternating use of high and low nitrogen containing dopant gas flow for sequentially deposited CVD diamond layer 148 of the plurality of CVD diamond layers relieve stress in the gem 151. For example, low to zero nitrogen dopant gas flow during bulk diamond deposition (e.g., for several layers 148 or for a thicker layer 148), followed by deposition of a thinner CVD diamond layer 152 shown in FIG. 1C using a higher or non-zero nitrogen dopant gas flow to form a nitrogen doped diamond stress relief layer. Then, the low to zero nitrogen flow may be resumed to deposit more bulk diamond (e.g., several additional layers 148 or another thicker layer 148) on the thinner stress relief layer 152. The sequence may be repeated to form several stress relief layers 152 in the gem 151. The stress relief layer(s) 152 act as color gradient region(s). Because the bulk of the gem 151 deposition is carried out with low to zero nitrogen flow, the color impact of the nitrogen dopant is reduced yet the stress relief is still provided in the gem 151.

Having described the system 100 carrying out one or more aspects of the exemplary method 200 (FIG. 2) to form a plurality of layers of crystalline material having a color gradient along a portion of a bulk object, attention is now turned to other aspects of jewelry fabrication that may be additionally or alternatively used to facilitate overcoming conventional jewelry design constraints. These aspects of jewelry fabrication are described separately herein for the sake of clear and efficient explanation. Accordingly, unless otherwise explicitly indicated or made clear from the context, the following aspects of jewelry fabrication shall be generally understood to be usable in combination with one another and/or with any one or more of the features described above.

A. Predetermined Color Gradients

While a predetermined color gradient has been described as being formed through controlling concentration of one or more dopants in a gas introduced into a volume via an intake system, other techniques for imparting a predetermined color gradient to a plurality of layers of crystalline material are additionally or alternatively possible. For example, as described in greater detail below, ion implantation may be used to introduce one or more dopants into a plurality of layers of material to form a predetermined color gradient. Additionally, or alternatively, as also described in greater detail below, getters may be used to form a predetermined color gradient in a plurality of layers. Further, or instead, radiation may be controllably delivered to a plurality of layers to form a predetermined color gradient.

i. Ion Implantation of Dopants to Form Predetermined Color Gradients

In an alternative embodiment, an ion implantation system (i.e., ion implanter) may be used to implant ions into the CVD diamond object (e.g., diamond gem) 151. Boron and/or nitrogen ions may be implanted to a selected depth into the gem 151 to create a color gradient region 152 thereon. In one embodiment, the boron and nitrogen ions may be implanted to different depths in the same gem 151 to create a color profile. Furthermore, the ions may be implanted through only a portion of the surface of the gem 151 to form the color gradient region 152 that is visible in only a portion gem 151 when viewed from the top. From example, the color gradient region 152 may be visible only in the middle and/or only on the edge(s) of the gem 151 when viewed from the top of the gem 151. As compared to in-situ doping of the CVD diamond gem, the ion implantation doping may provide additional control over placement of the one or more dopants, thus offering additional variation in imparting the predetermined color gradient 152 to the gem 151.

ii. Getters Improve Color Gradient

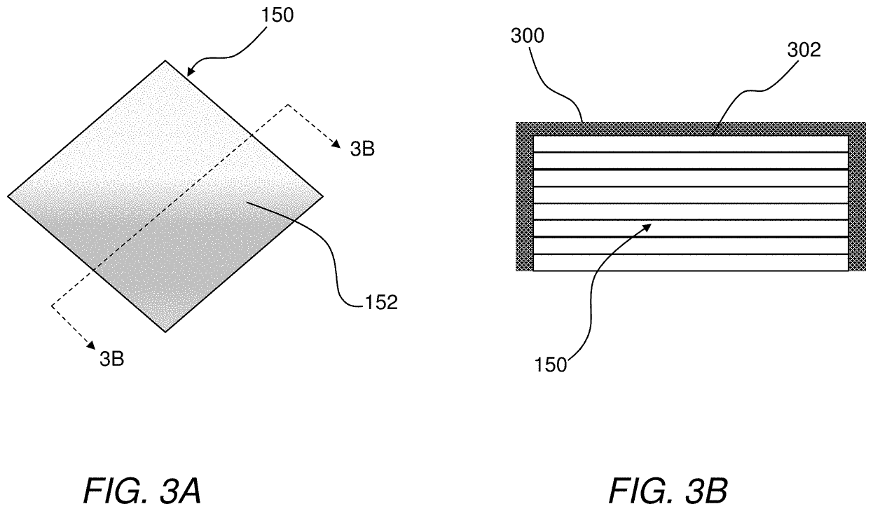

Referring now to FIGS. 3A-3B, a getter 300 layer or region is formed on or in the gem 151. The getter 300 may include nickel, phosphorus, or a combination thereof, which may advantageously scavenge nitrogen impurities toward the getter 300 during annealing of the gem 151. For example, the bulk object (e.g., gem) 151 may include the getter 300 distributed on the plurality of layers 150 along a surface region 302 of the bulk object 151. Continuing with this example, the getter 300 may contribute to scavenging nitrogen impurities (if a yellowish color is not desired) from the plurality of layers 150 toward the surface region 302 of the bulk object 151 to improve color quality in a portion of the bulk object 151 away from the surface region 302. While the getter 300 has been described as being distributed on the surface region 302, it shall be appreciated that the getter 300 may, further or instead, be distributed within any one or more other portions of the plurality of layers 150 (e.g., according to a predetermined pattern within a given layer). The getter 300 layer may be formed by sputtering or CVD on the surface of the gem 151. Alternatively, the getter 300 region may be formed near the surface of the gem 151 by incorporating a getter source gas, such as phosphine from a separate dopant gas source, in the apparatus 100 in-situ during the deposition of the first and/or last CVD diamond layer 148 of the plurality of layers 150. Thus, the getter 300 gas (e.g., phosphine) may be mixed with the precursor gas 144 in the intake system 102 and deposited onto a layer 148 of crystalline material via chemical vapor deposition in a manner analogous to deposition of one or more dopants introduced into the volume 118 via the intake system 102, as described above. Alternatively, the getter 300 region may be formed by ion implanting getter ions into one or more surfaces of the gem 151.

In certain implementations, annealing may be used to increase mobility of an impurity, such as nitrogen, toward the getter 300. For example, returning to the example of the getter 300 deposited along the surface region 302 of the bulk object 151 (e.g., through ion implantation, in-situ CVD or surface coating via sputtering or CVD, or a combination thereof), the bulk object 151 may be annealed to facilitate movement of nitrogen atoms toward the surface region 302, leaving a lower concentration of nitrogen atoms toward a middle portion of the bulk object 151. The difference in color associated with such a distribution of nitrogen atoms shall be understood to be a predetermined color gradient. Further, while the bulk object 151 may be annealed, it shall be appreciated that one or more layers of the plurality of layers 150 may be annealed after synthesis of a given layer and prior to synthesis of a subsequent layer. The surface region 302 containing the getter 300 and gettered nitrogen atoms may be removed after annealing by polishing, grinding and/or etching the surface of the bulk object (e.g., gem) 151.

iii. Radiation to Form Predetermined Color Gradients

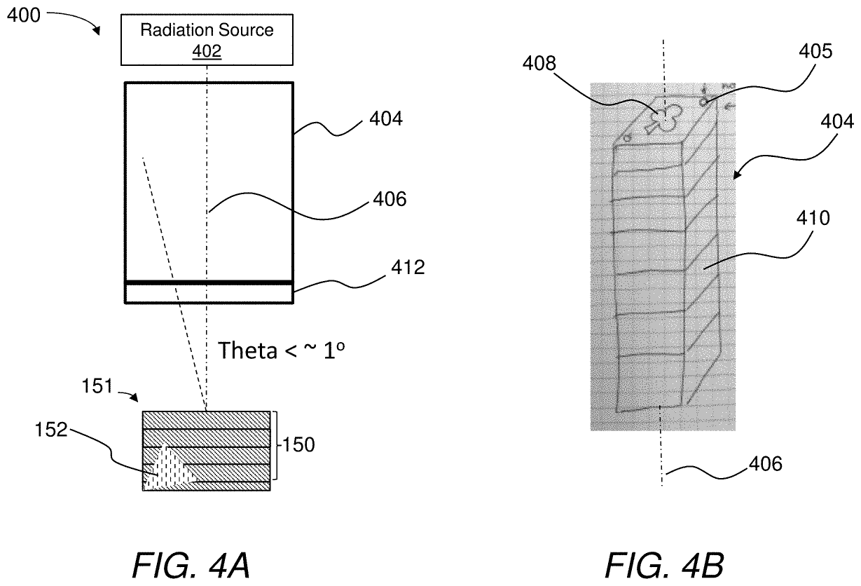

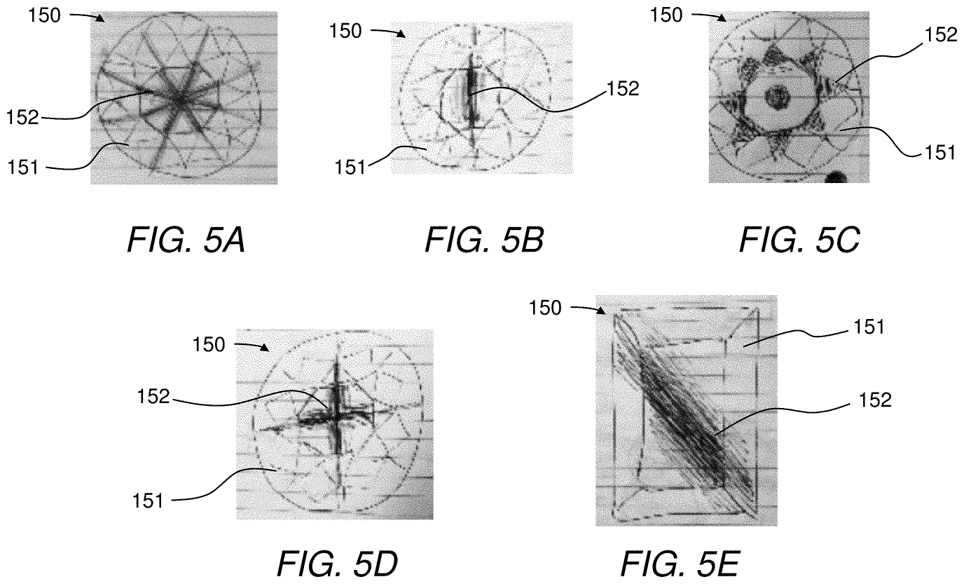

Referring now to FIGS. 4A-4B and 5A-5E, a processing station 400 may include an ionizing radiation source 402 and a collimator 404. As described in greater detail below, the radiation source 402 and the collimator 404 may be used in coordination with one another to irradiate the plurality of layers 150 to one or more depths with ionizing radiation associated with the predetermined color gradient.

In general, the collimator 404 may be positioned between the radiation source 402 and the plurality of layers 150 of crystalline material forming at least a portion of the bulk object 151. It shall be appreciated that, in such implementations, the plurality of layers 150 may or may not have a predetermined color gradient imparted thereon prior to exposure to radiation from the radiation source 402 in the processing station 400. Further, or instead, it shall be understood that the radiation techniques described with respect to the processing station 400 may be carried out in the volume 118 defined by the chamber 108 (FIGS. 1A-1C), with respect to as many layers as desired, and that the processing station 400 is described separately here for the sake of clarity of explanation.

The radiation source 402 may emit any one or more of various different types of ionizing radiation useful for creating a pattern in the plurality of layers 150 of the bulk object 151. Ionizing radiation may include subatomic particles, such as alpha particles, beta particles and/or neutrons, and/or ionizing electromagnetic radiation, such as gamma rays and/or X-rays, which can damage the bulk object 151 and create the color gradient region 152 in the bulk object. As an example, the ionizing radiation source 402 may include Cobalt-60. Thus, continuing with this example, radiation directed from the radiation source 402 toward the plurality of layers 150 of crystalline material forming at least a portion of the bulk object 151 may include gamma radiation and/or beta particles. Other ionizing radiation sources 402, such as X-ray sources and/or radioactive material sources may be used.

In general, the collimator 404 between the radiation source 402 and the plurality of layers 150 of the bulk object 151 may be formed of a high-cross section material (e.g., steel, lead, plastic, or a combination thereof) to block the ionizing radiation from the portion(s) of the gem 151 such that the radiation reaches the gem 151 in a predetermined pattern through the opening(s) 408 in the collimator 404.

In certain implementations, the collimator 404 may define an opening 408 along an axis 406 defined by the radiation source 402 and the plurality of layers 150. Radiation from the radiation source 402 may pass through the opening 408 relatively unblocked compared to radiation incident on material of the collimator 404, with the result being the formation of a pattern, in the shape of the opening 408, on the plurality of layers of 150 of the bulk object 151. Thus, the collimator 404 acts as a patterned mask to ionizing radiation from the radiation source 402, similar to a function of a photoresist mask during selective etching of regions of a semiconductor device.

The opening 408 of the pattern may be in a shape of a letter or letters or symbols to create a monogrammed gem 151 and/or a gem 151 containing symbols. Examples of such patterns include, but are not limited to a pattern augmenting a facet pattern of a cut stone (FIG. 5A), a cat's eye pattern (FIG. 5B), a flower pattern (FIG. 5C), a cross (FIG. 5D), or a shading effect (FIG. 5E). The shading effect of FIG. 5E may be generated by using a thickness of the collimator 404 that allows some but not all ionizing radiation to pass through the edges of the pattern adjacent to the opening 408. Thus, the shaded regions in the gem 151 are damaged less than the regions which are directly irradiated by the ionizing radiation through the opening 408 in the collimator 404. More generally, any of various different predetermined pattern (e.g., crystalline lattice damage) formed by the radiation in the gem 151 shall be understood to be a type of predetermined color gradient 152 to the plurality of layers 150 of the gem 151.

To facilitate control over the predetermined color gradient imparted to the plurality of layers 150, the collimator 404 may direct radiation from the radiation source 402 into the plurality of layers 150 in a consistent direction. For example, the collimator 404 may have a height along the axis 406 suitable for directing radiation from the opening 408 into the plurality of layers 150 in a direction substantially parallel to the axis 406 and, thus, substantially parallel to the direction of radiation emitted at the radiation source 402. As a more specific example, the collimator 404 may have a height corresponding to less than about one degree alignment of the radiation emitted by the radiation source 402. That is, stated in terms of alignment with the axis 406, the collimator 404 may have a height sufficient to align the radiation emitted by the radiation source 402 to be substantially parallel to the axis 406 to within about one degree.

In certain implementations, the height of the collimator 404 along the axis 406 may be adjustable. For example, the collimator 404 may include modules 410 stackable on top of one another to adjust the height of the collimator 404, as shown in FIG. 4B. Each module 410 may include dowel holes 405, such that dowels may be inserted into the dowel holes 405 in each stack of modules 410 to align the modules in the collimator 404. Thus, returning to the example of alignment of the radiation emitted by the radiation source 402, the height of the collimator 404 may be adjusted by adding or removing instances of the modules 410 to achieve the height corresponding to about one degree alignment of the radiation emitted by the radiation source 402 to create shading effects in the gem 151. In some instances, ligaments may extend across the opening 408 to facilitate forming a concentric pattern. In such cases, the ligaments may be formed with a low-cross section (e.g., thin metal or thin plastic) such that the ligaments do not significantly block the ionizing radiation. That is, more generally, the collimator 404 may be include variations in thickness to facilitate blocking and permitting radiation as necessary to form a predetermined pattern in the plurality of layers 150 of crystalline material forming at least a portion of the bulk object 151.

The processing station 400 may additionally, or alternatively, include a collimation filter 412, as may be useful for filtering at least a portion of the radiation emitted by the radiation source 402 to form a predetermined gradient in the plurality of layers 150 of the bulk object 151. The collimation filter 412 may be positioned between the collimator 404 and the bulk object 151 to facilitate imparting a predetermined gradient in the plurality of layers 150 of the bulk object 151. As an example, in instances the predetermined gradient to be imparted to the plurality of layers 150 is a pattern augmenting the facet pattern of a cut stone (FIG. 5A), the collimation filter 412 may be shaped to absorb radiation according to the pattern.

B. Gas Purification

While systems for forming bulk objects including a plurality of layers of a synthesized, crystalline material have been described as including gas from commercial sources with specified purity and certain types of purifiers 129, 131 shown in FIG. 1A, other configurations are additionally or alternatively possible to achieve high purity of source gases used in any one or more of the various different synthesis techniques described herein. For example, introducing a reactant gas into a volume for chemical vapor deposition may include a double-loop purification system for forming purified methane as a precursor gas introduced into any one or more of the CVD reactors described herein. Additionally, or alternatively, introducing a reactant gas into a volume for chemical vapor deposition may include renewable-based formation of hydrogen and methane as a precursor gas introduced into any one or more of the CVD reactors described herein.

i. Double-Loop Purification of Methane

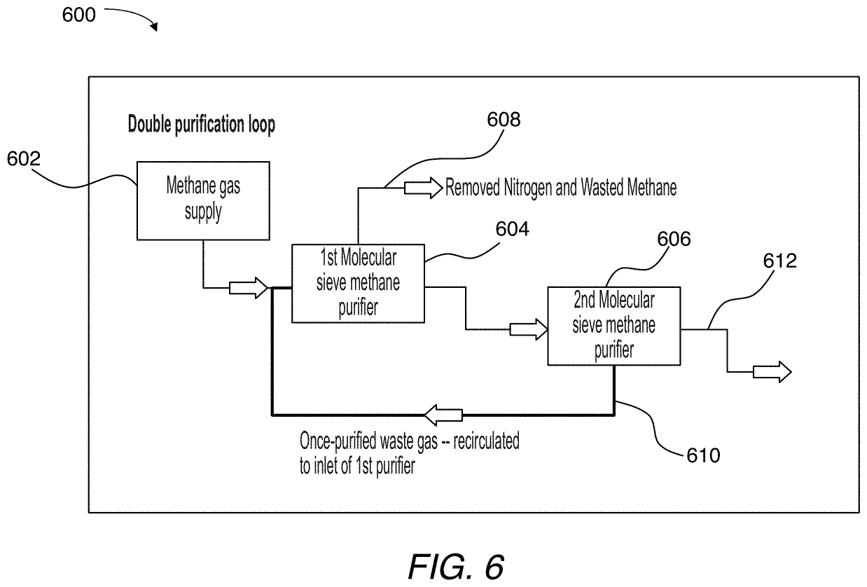

Referring now to FIG. 1A and FIG. 6, a purification system 600 may purify methane by removing trace amounts of nitrogen that are often found in commercially sourced methane. Unless otherwise specified or made clear from the context, the purification system 600 shall be understood to be operable in coordination with the intake system 102 to deliver purified methane in a precursor gas delivered by the intake system 102 into the volume 118 via the inlet port 122. As an example, the purification system 600 may be used in combination with either one of the first gas source 128 or the second gas source 130 in addition to or instead of the respective purifiers 129 and 131 to deliver purified methane to the volume 118 during operation of the system 100. For example, the purification system 600 may be used with the second gas source (e.g., methane gas source) 130 instead of the purifier 131.

In general, the purification system 600 may include a methane supply 602 (e.g., a methane gas cannister), a first molecular sieve 604, a second molecular sieve 606, a waste vent 608, a return loop 610, and an outlet vent 612. The methane supply 602 may be in fluid communication with the first molecular sieve 604, where methane from the methane supply 602 moves through the first molecular sieve 604 is separated into a waste gas directed to the waste vent 608 and a first intermediate gas directed from the first molecular sieve 604 to the second molecular sieve 606. The second molecular sieve 606, in turn, separates the first intermediate gas into purified methane directed to the outlet vent 612 and into a second intermediate gas returned, along the return loop 610, to a point upstream of the first molecular sieve 604. The purified methane that is directed to the outlet vent 612 may be ultimately provided to the inlet port 122 and into the volume 118, where the purified methane may be exposed to energy from the energy source 116 and broken down facilitate synthesis of crystalline material according to any one or more of the CVD techniques described herein. Further, or instead, the second intermediate gas returned along the return loop 610 may mix with methane from the methane supply 602 and directed into first molecular sieve 604 to move through the purification system 600 again.

As may be appreciated from the foregoing example, at least a portion of the methane originating from the methane supply 602 may move through the first molecular sieve 604 and the second molecular sieve 606 multiple times. Accordingly, for the same initial composition of the methane from the methane supply 602, the purified methane at the outlet vent 612 may have a lower concentration of contaminants (e.g., N₂) than methane that has gone through each of the first molecular sieve 604 and the second molecular sieve 606 only once. By reducing concentration of contaminants in at least one component of a precursor gas delivered by the intake system 102, the purification system 600 may reduce the likelihood of imperfections in the plurality of layers of crystalline material formed in the CVD reactor 104.

ii. Renewable-Based Formation of Hydrogen and Methane

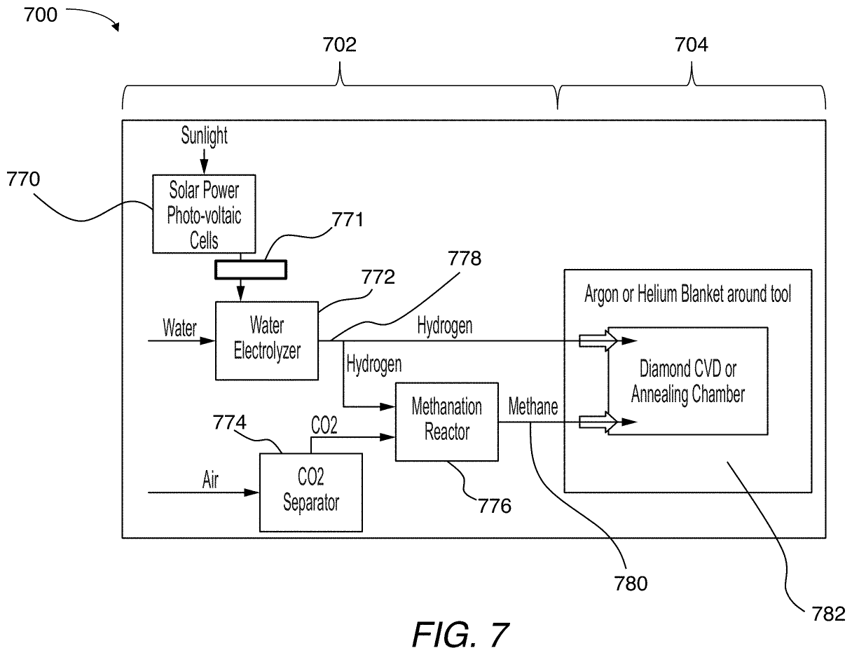

Referring now to FIG. 7, a system 700 may include an intake system 702, a CVD reactor 704, and a controller 706. The controller 706 may be in electrical communication with the intake system 702 and the CVD reactor 704. In use, the controller 706 may control the intake system 702 and the CVD reactor 704 to synthesize crystalline material (e.g., diamond) in the CVD reactor 704 from renewable sources such as sunlight, air, and water processed in the intake system 702, as described in greater detail below. For the sake of clear and efficient description, elements of the system 700 should be understood to be analogous to or interchangeable with elements of system 100 corresponding to 100-series element numbers (e.g., in FIGS. 1A-1C) described herein, unless otherwise explicitly made clear from the context and, therefore, are not described separately from counterpart 100-series element numbers, except to note difference or emphasize certain features. Thus, for example, the CVD reactor 704 of the system 700 should be understood to be analogous to the CVD reactor 104 of the system 100 (FIGS. 1A-1C), except any extent indicated. Further, or instead, the controller 706 may control any one or more of various components of the system 100 to carry out any one or more aspects of various fabrication techniques described herein, such as those described with respect the exemplary method 200 (FIG. 2) and, further or instead, any one or more aspects of fabrication techniques described below with respect to forming crystalline material from one or more of sunlight, air, and water processed in the intake system 702.

In general, the intake system 702 may include a renewable power generation device, such as photovoltaic cells 770 and/or a wind turbine, a storage system 771, an electrolyzer 772, a carbon dioxide separator 774, and a methanation reactor 776 in communication with one another to form a hydrogen stream 778 and a methane stream 780. While the hydrogen stream 778 and the methane stream 780 are shown as separate streams introduced into the CVD reactor 704 through separate conduits, it shall be understood that the hydrogen stream 778 and the methane stream 780 may be combined with one another for introduction into the CVD reactor 704 in the same conduit as may be necessary or useful.

The photovoltaic cells 770 may convert sunlight received at the photovoltaic cells 770 to produce electricity. Alternatively or additionally, a wind turbine may convert wind into electricity (e.g., AC power which may be converted to DC power using an AC/DC inverter). At least a portion of the electricity produced by the renewable power generation device, such as the photovoltaic cells 770 may be stored in the storage system 771 to account for temporal variation in electrical load of the electrolyzer 772. For example, the storage system 771 may be one or more of a battery, an ultracapacitor, or a flywheel with capacity to store energy that may be delivered at varying rates to meet variable electrical demands of the electrolyzer 772. The electricity from the storage system 771 and/or directly from the renewable power generation device may be provided to the electrolyzer 772 as DC power to drive electrolysis of water provided into the electrolyzer 772 to produce atomic hydrogen (H₂) and atomic oxygen (O₂). Importantly, the atomic hydrogen produced by the electrolyzer 772 may be substantially free of nitrogen may be delivered to CVD reactor 704 to facilitate synthesis of high-quality crystalline material (e.g., crystalline material that is substantially free of nitrogen impurities) according to any one or more of the techniques described herein. Additionally, or alternatively, the atomic hydrogen may be used to form methane in the intake system 702, as will now be described.

The carbon dioxide separator 774 may receive air moved into the carbon dioxide separator 774 under pressure and remove at least some of the carbon dioxide from the incoming air (e.g., through membrane separation, adsorption, or a combination thereof) to produce a stream of carbon dioxide. The stream of carbon dioxide produced by the carbon dioxide separator 774 and at least a portion of the hydrogen stream 778 produced by the electrolyzer 772 may be delivered to the methanation reactor 776 to produce a stream of methane 780. For example, the methanation reactor 776 may include one or more catalytic materials (e.g., one or more of nickel, ruthenium, or rhodium) that promote formation of methane from atomic hydrogen and carbon dioxide. Methane formed from atomic hydrogen and carbon dioxide in the methanation reactor 776 may be substantially free of impurities. Accordingly, in the substantial absence of impurities such as nitrogen, the stream of methane may be delivered to the CVD reactor 704 to facilitate synthesis of high-quality crystalline material according to any one or more of the various different techniques. Accordingly, in combination, the processes carried out by the intake system 702 may facilitate synthesizing a crystalline material, such as diamond, using only sunlight, water, and air as raw materials.

In some implementations, the system 700 may include an overpressure region 782 that surrounds the CVD reactor 704 and/or plumbing conduits and load/unload areas of the CVD reactor 704. In use, the overpressure region 782 may be positively pressurized with an inert gas, such as one or more of helium, argon, neon, or another noble gas. Thus, to the extent the CVD reactor 704 has leaks, the gas moving into the CVD reactor 704 via such leaks is the inert gas, rather than air. That is, the use of inert gas in the overpressure region 782 may reduce inadvertent introduction of nitrogen into the CVD reactor 704 such that alone, or in combination with nitrogen-free formation of hydrogen and methane, the overpressure region 782 may reduce the likelihood of introducing impurities into crystalline material synthesized in the CVD reactor 704.

The intake system 702 has been described as producing electricity using sunlight as a renewable energy source. However, other renewable energy sources may additionally or alternatively be used. For example, wind power or hydroelectric power may additionally, or alternatively, be used to provide electricity sufficient to meet the power demands associated with forming hydrogen and methane from water and air. Given that each of these renewable energy sources may be implemented without the need to tap into the energy grid, it shall be appreciated that the synthesis of crystalline material from water and air may be achieved in regions in which the electrical grid is unreliable or even nonexistent. If needed, grid power may be used as backup power in case power from the renewable power generation device or energy storage is not available.

C. Detecting Shifts in Chemical Vapor Deposition Conditions

While chemical vapor deposition techniques have been described as proceeding according to certain prescribed conditions that may be monitored (e.g., vacuum pressure, purity levels), other forms of monitoring may be additionally or alternatively be used to facilitate achieving synthesis of high-quality crystalline material that substantially corresponds to a model and, more generally, meets exacting standards of a particular jewelry design.

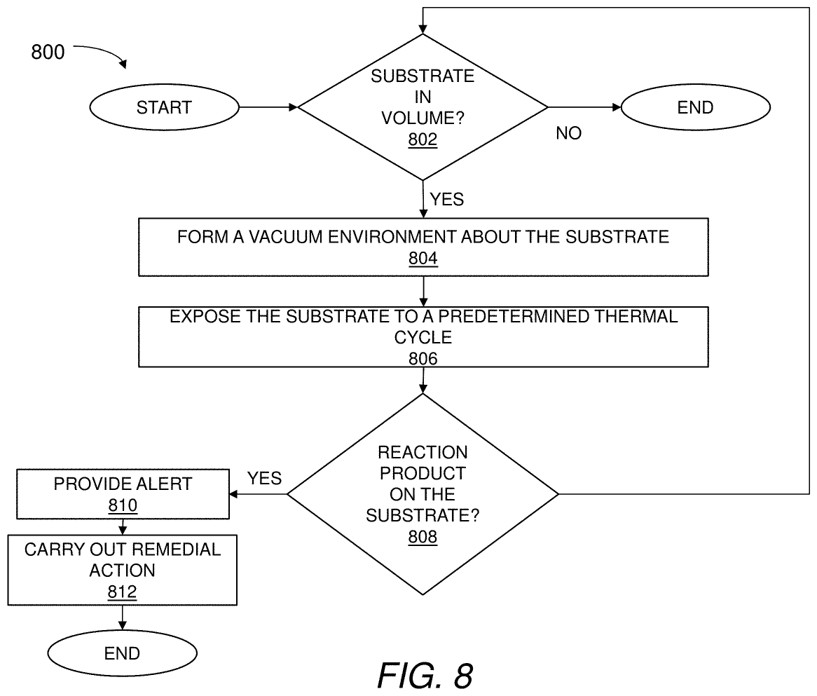

Referring now to FIG. 8, an exemplary method 800 may include monitoring conditions associated with synthesis of crystalline material (e.g., CVD diamond) may include detecting a shift in conditions based on detecting a particular reaction produce formed on the support. Unless otherwise specified or made clear from the context, one or more aspects of the exemplary method 800 may be implemented using any one or more of the various different systems (e.g., 100 or 700), and components thereof, described herein. As a more specific example, any one or more aspects of the exemplary method 800 may be implemented as computer-readable instructions stored on the computer-readable storage medium 138 (FIG. 1A) and executable by the processing unit 136 (FIGS. 1A-1C) of the controller 106 (FIG. 1A) to operate the system 100 (FIG. 1A). For example, the exemplary method 800 may facilitate monitoring shifts in thermal characteristics of the volume 118 (FIG. 1A) in response to heat delivered by the heater 114 (FIG. 1A). Additionally, or alternatively, the exemplary method 800 may facilitate monitoring the extent of leaks that may have developed in the CVD reactor 104 (FIG. 1A) over time. The exemplary method 800 may be carried out, for example, periodically between fabrication of bulk objects to facilitate taking one or more remedial actions useful for achieving consistent quality in the fabrication of the bulk objects.

As shown in step 802, the exemplary method 800 may include detecting a dummy substrate in a volume defined by a chamber. In this particular context, the dummy substrate may be a bare (i.e., uncoated) dummy silicon wafer to facilitate using the dummy substrate as a sensor indicative of shifts in one or more conditions in the volume defined by the chamber. In certain implementations, the dummy substrate may be placed in the volume 118 on the susceptor or other support 112. This position of the dummy substrate in the volume may be detected based on detecting weight of the dummy substrate in place, a switch depressed by the dummy substrate in place, optical techniques, a user input following placement of the dummy substrate in the volume, or a combination thereof. In other implementations, the dummy substrate may be a material other than a silicon wafer that can form a reaction product on its surface (e.g., an oxide and/or a nitride coating). For example, the dummy substrate may be a pyrometric cone (e.g., furnace cone that is typically used to measure heat work during firing of ceramics) or a firing ring (e.g., one of a set of flat ceramic (e.g., clay) rings that are placed in a pottery kiln that are withdrawn successively as the pottery firing proceeds, where the amount of shrinkage of the ring indicating the intensity of the fire in the kiln). Further, or instead, in such implementations, it shall be appreciated that the monitoring techniques set forth with respect to the exemplary method 800 may be carried out while synthesis of crystalline material is taking place in the volume.

As shown in in step 804, the exemplary method 800 may include forming a vacuum environment about the dummy substrate detected in the volume. In such a vacuum environment, vacuum pressures about the dummy substrate in the volume may be the same as or comparable to pressures associated with fabrication to synthesize crystalline material in the volume. Accordingly, formation of the vacuum pressure may be carried out according to any one or more of the various different approaches described herein for forming vacuum pressure in the volume.

As shown in step 806, the exemplary method 800 may include exposing the dummy substrate in the vacuum environment to a predetermined thermal cycle. Returning to the example in which the heater is a furnace and the dummy substrate includes one or more of a cone or a firing ring disposed in the volume, this may include controlling the furnace, disposed in the volume, according to the predetermined thermal cycle. In some instances, the combination of the predetermined thermal cycle and the vacuum environment may substantially replicate operating conditions associated with synthesis of crystalline material such that the exemplary method 800 may provide an accurate assessment of drifting conditions actually experienced during fabrication. Thus, for example, the predetermined thermal cycle may include exposing the dummy substrate to a target temperature of greater than about 600° C. and less than about 800° C. for a predetermined period of time. In some implementations, however, the predetermined thermal cycle may be carried out at a lower temperature and/or at a shorter time scale than otherwise used during fabrication to facilitate rapid assessment of drift in one or more conditions, such as may be useful for achieving high throughput while maintaining control over quality of the fabricated objects.

Generally, conditions under which the dummy substrate in the vacuum environment is exposed to the predetermined thermal cycle may be at least partially based on the operational parameter that is to be monitored using the exemplary method 800. For example, in instances in which the exemplary method 800 is carried out to detect leakage into the volume, exposing the dummy substrate in the volume to the predetermined thermal cycle may include flowing an inert gas over the dummy substrate during the predetermined thermal cycle, as described in greater detail below. As also described in greater detail below, in instances in which the exemplary method 800 is carried out to detect a shift in thermal performance of the system, exposing the dummy substrate in the volume to the predetermined thermal cycle may include providing an oxidizing environment to the dummy substrate.

As shown in step 808, the exemplary method may include, on the dummy substrate in the vacuum environment, detecting a reaction product formed by a material of the dummy substrate and a reactant drawn into the vacuum environment from outside of the chamber. In general, the reaction product may be an oxide of a material forming at least a portion of the dummy substrate. For example, in instances in which the dummy substrate is formed of silicon, the reactant product is SiO₂. In some cases, the presence of SiO₂ may be detected with the dummy substrate in situ in the volume, such as through the use of one or more optical techniques or, in some cases, detecting a change in concentration of the reactant at the inlet and at the outlet of the chamber. Here again, however, it should be appreciated that drawing the reactant into the vacuum environment may context specific—the reactant drawn into the vacuum environment via a defined inlet and at a controlled concentration in instances in which temperature shift is monitored and the reactant drawn into the vacuum environment via inadvertent leaks and with an uncontrolled concentration in instances in which leak detection is monitored. Each of these contexts is described in greater detail below.

As shown in step 810, the exemplary method 800 may include, based on detection of the reaction product on the dummy substrate, providing an alert associated with a shift in a chemical vapor deposition process parameter for synthesis of crystalline material in the volume. The alert may generally provide an indication that a remedial action may be required with respect to the parameter being monitored. In some instances, the alert may be generated on a user interface (e.g., the user interface 139 of the controller 106 in FIG. 1A) upon receiving an indication that the reaction product has been detected. Additionally, or alternatively, the alert may include disabling the ability of the system to operate under fabrication conditions until the condition is acknowledged by a user. Further, or instead, providing the alert may include providing, at a user interface, an indication of an amount of drift detected (e.g., a temperature difference or a leak rate, as the case may be).

As shown in step 812, the exemplary method 800 may include carrying out a remedial action in response to the alert associate with the shift in the chemical vapor deposition process parameter. The remedial action may be based on the process parameter being monitored. Additionally, or alternatively, the remedial action may be based on a severity of the alert. As an example, low-severity alerts may correspond to small remedial actions (e.g. fine adjustments to one or more parameters) while high-severity alerts correspond to shutting down the system.

While various different aspects of the exemplary method 800 may be carried out automatically, it shall be appreciated that some aspects of the exemplary method 800 may be carried out by an operator. Thus, for example, detecting the presence of the reactant product on the dummy substrate may include visual inspection by an operator and/or ex situ testing, with the results of each of these being notable to the controller via a user interface (e.g., the user interface 139 of the controller 106).

Having described the exemplary method 800 in terms of general monitoring of drift in CVD parameters, attention is turned now to description of the use of the exemplary method 800 to carry out monitoring of two important CVD parameters that can drift over time—namely, leak monitoring and temperature monitoring.

i. Leak Monitoring

Given the various different components associated with the CVD reactors described herein, it shall be appreciated that leaks may develop as components shift or degrade over time or that leaks may be present upon initial installation. As is true in these cases, and of leaks in general, the presence of a leak may be difficult to detect, apart from observing the deleterious impact of the leak on the synthesized crystalline material. The exemplary method 800 may be carried out to provide a determination of whether a leak is present. This determination is often valuable for the binary information it conveys—namely, leak or no leak—given that the no leak condition is often an indispensable requirement. However, in some instances, the amount of reactant formed within a given period may provide at least a qualitative indication of the degree to which leakage is present and, thus, the degree to which leakage is impacting fabrication quality.

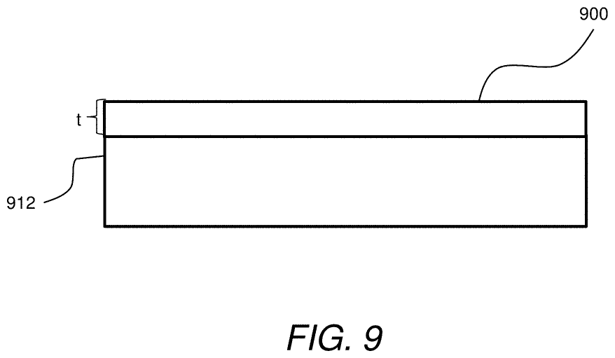

In one embodiment, a method of leak testing a chemical vapor deposition (CVD) apparatus 100 or 700, comprises placing a dummy substrate 912 shown in FIG. 9 in a chamber 104 or 704 of the CVD apparatus, forming a vacuum environment in the chamber, providing an inert gas (e.g., a noble gas, such as argon, helium, neon, etc.) into the chamber and subjecting the dummy substrate to a predetermined thermal cycle in the chamber. The method also includes detecting (e.g., optically, etc.) if a reaction product 900 of air and a material of the dummy substrate 912 is formed on the dummy substrate, and providing an alert (e.g., visible, audible and/or a controller command) indicative of a leak in the chamber based on detection of the reaction product 900 on the dummy substrate.

In one embodiment, the dummy substrate 912 comprises a bare silicon wafer, and the reaction product 900 comprises a silicon oxide layer. In this embodiment, subjecting the dummy substrate 912 to the predetermined thermal cycle includes heating the dummy substrate to a target temperature of greater than about 600° C. and less than about 800° C. for a predetermined period of time, such as about one minute. In another embodiment, the dummy substrate 912 comprises a pyrometric cone or a firing ring, and the reaction product 900 comprises a visible coating on the cone or ring surface. In yet another embodiment, the dummy substrate 912 comprises one or more of lithium, magnesium or boron, and the reaction product 900 comprises a lithium nitride, magnesium nitride or boron nitride layer.

If no air leak is detected, then CVD diamond is grown in the chamber. In one embodiment, the method also includes pressurizing an environment outside of the chamber 704 with an inert gas (e.g., noble gas), as discussed above with respect to FIG. 7, in response to providing the alert indicative of the leak.

In general, the exemplary method 800 may be used to detect leaks by detecting whether or not air is being drawn into the vacuum environment over the dummy substrate. For example, exposing the dummy substrate in the vacuum environment to the predetermined thermal cycle may include flowing a first inert gas (e.g., argon) over the dummy substrate during the predetermined thermal cycle (e.g., about 800° C. for about 60 seconds). Under such conditions, the only path (or paths) along which a reactant (e.g., a component of air) may be drawn into the vacuum environment, from outside of the chamber, is through one or more leak paths between the vacuum environment and an environment outside of the chamber.

As an example, in the case in which the environment outside of the chamber is air and the dummy substrate includes bare silicon, the only way that a silicon oxide can form on the dummy substrate (while the first inert gas is provided in the vacuum environment) is through air being drawn into the vacuum environment via one or more leak paths from the outside environment into the vacuum environment. Thus, continuing with this example, the presence of silicon oxide in the vacuum environment provides an indication of leakage from the outside environment into the vacuum environment. This information may be informative on its own. However, in some instances, the location of the silicon oxide formed on the bare silicon dummy substrate may, further or instead, be useful for identifying the source of the one or more leak paths. While the foregoing example has been described in terms of oxidation of a bare silicon dummy substrate, other combinations of materials may additionally or alternatively be used to detect leakage according to the exemplary method 800. For instance, the dummy substrate may be formed of one or more materials reactable with the nitrogen component of air to provide an indication of leakage. Examples of such materials include lithium, magnesium, boron, or a combination thereof, which form lithium nitride, magnesium nitride or boron nitride. Given the reactivity of these materials with nitrogen, these materials may useful for implementing leakage detection using a thermal cycle of less than about 800° C.

In the context of leakage detection, a remedial action carried out according to the exemplary method 800 may include servicing the system 100 and/or pressurizing the environment outside of the volume with a second inert gas in response to the alert indicative of the leak. For example, the second inert gas may be delivered to an overpressure region (e.g., the overpressure region 782 of the system 700 in FIG. 7). In general, while the flow of the second inert gas does not stop the leak, providing the second inert gas to the environment outside of the volume may effectively stop the flow of air into the vacuum environment and, in turn, this may reduce or eliminate the inadvertent flow of contaminants (e.g., elemental nitrogen) through the one or more leak paths. While the first inert gas and the second inert gas may be different from one another in some instances, it shall be understood that the first inert gas and the second inert gas may be the same gas, as may be useful for simplifying materials required for carrying out the exemplary method.

ii. Temperature Monitoring

Various aspects of synthesis techniques described herein are sensitive to temperature inside of the volume. While temperature sensors may provide information regarding temperature at various points along the volume, accurate temperature sensing on the support itself is generally difficult or impossible in some cases. Accordingly, a predetermined target temperature at some position in a given system may be used as a proxy for the temperature on the support itself. However, over time and/or under changing operating conditions, the correspondence between the predetermined target temperature and the actual temperature of the support may change. Given that synthesis of crystalline material takes place on the support, the change in correspondence between the predetermined target temperature and the actual temperature of the support may have a large impact on the synthesis of crystalline material, even as the predetermined target temperature remains nominally the same.

In one embodiment, method of calibrating a temperature of a chemical vapor deposition (CVD) apparatus 100 or 700 includes placing a dummy substrate 912 in a chamber 104 or 704 of the CVD apparatus, forming a vacuum environment in the chamber, providing a reactant into the chamber 104 or 704 and subjecting the dummy substrate to a predetermined temperature in the chamber, forming a reaction product layer 900 of the reactant and a material of the dummy substrate on the dummy substrate 912, determining (e.g., optically or electrically) a thickness of the reaction product layer, and determining if the temperature of the CVD apparatus is properly calibrated based on comparing the determined thickness of the reaction product layer to a stored (e.g., in the storage medium 138) thickness value of the reaction product layer for the predetermined temperature.

In one embodiment, the dummy substrate 912 comprises a bare silicon wafer, the reactant comprises an oxygen containing gas (e.g., oxygen, water vapor, etc.) and the reaction product layer 912 comprises a silicon oxide layer. In another embodiment, the dummy substrate 912 comprises one or more of lithium, magnesium or boron, the reactant comprises a nitrogen containing gas and the reaction product layer 900 comprises a lithium nitride, magnesium nitride or boron nitride layer. If the temperature of the CVD apparatus is properly calibrated, then CVD diamond is grown in the chamber.

Accordingly, the exemplary method 800 may be carried out to monitor a drift in correspondence between the predetermined target temperature (which may be set as an input to the heater through a user interface) and the actual temperature of the support under such conditions. For example, referring now to FIGS. 8 and 9, a reactant is drawn into the vacuum environment from outside of the chamber while the dummy substrate 912 is heated to a target temperature (e.g., a temperature used to oxidize bare silicon, such as 600 to 800 degrees Celsius) for a predetermined time (e.g., one minute) followed by ramping the temperature back down below the reaction (e.g., oxidation) temperature. The reactant may be a substantially fixed volumetric flow of oxygen during the predetermined thermal cycle. In this context, the substantially fixed volumetric flow of oxygen shall be understood to be a flow rate varying from a nominal value by less than about ±2 percent, (e.g., less than about ±1 percent). As this substantially fixed volumetric flow of oxygen reacts with the material (e.g., bare silicon) of the dummy substrate 912, an oxidation reaction proceeds on the dummy substrate to form the reaction product 900 (e.g., silicon oxide layer) to a thickness “t” on the dummy substrate 912. Continuing with this example, detecting the reaction product formed by the material of the dummy substrate and the reactant drawn into the vacuum environment from outside of the chamber may include measuring thickness of the reaction product on the dummy substrate. For example, the dummy substrate may be removed from the chamber and the thickness of the reactant product may be measured using optical or electrical measurement methods. Additionally, or alternatively, the thickness of the reactant product on the dummy substrate may be measured in situ in the chamber (e.g., via optical measurement through an observation port of the chamber).

In general, with other parameters of the chamber fixed and known, the thickness of the reactant product on the dummy substrate may be understood to be a function primarily of the temperature on the dummy substrate. Thus, for example, at a first time of operation of the system 100 (FIG. 1A), a fixed thermal profile may be executed in the volume 118 (FIG. 1A) (e.g., ramping to a typical temperature associated with oxidation of silicon, holding the temperature for 60 seconds, and ramping the temperature back down). The thickness “t” and distribution of thickness of the reaction product 900 (e.g., SiO₂) grown on the dummy substrate 912 may be measured. A correlation of thickness “t” to different temperatures (for the same ramping profile) may be determined by repeating formation and measurement of the reaction product 900 in steps of target temperature (e.g., about 20° C.). This correlation may be a baseline (or predetermined) relationship by which temperature drift may be assessed.

As an example, at a later time, the thickness “t” of the reaction product 900 on the dummy substrate 912 may be measured at a given target temperature. If the thickness “t” of the reactant product 900 measured at the later time is the same as the thickness “t” of the reactant product 900 measured in the baseline relationship between thickness and target temperature, the temperature characteristics of the system in the vicinity of the dummy substrate may be considered unshifted. If, however, the thickness “t” of the reaction product 900 measured at the later time is not the same as the thickness “t” of the reactant product 900 measured in the baseline relationship between thickness of the reactant product and target temperature, the temperature characteristics of the system in the vicinity of the dummy substrate 912 may be considered shifted. The alert provided according to the exemplary method 800 may be based on observation of such a deviation of the later measurement of thickness from the baseline relationship. Further, in some instances, a comparison of the later measurement to the baseline relationship may provide a quantitative indication of the shift in temperature characteristics of the system in the vicinity of the substrate. Thus, continuing with this example, the alert may include an indication of the temperature difference (or shift) associated with the deviation of the later measurement of thickness from the baseline relationship between the thickness of the reaction product and the target temperature in the volume.

D. Forming a Bulk Object from Fragments

Having described various aspects of synthesizing a plurality of layers of crystalline material having a predetermined color gradient and general aspects of gas purification and process monitoring, attention is now turned to description of techniques for synthesizing crystalline material to join a plurality of fragments of crystalline material to form a bulk object. Through the selection of the size, shape, color, and relative placement of the fragments of crystalline material, the bulk object may have any one or more of various different mosaic appearances that facilitate making efficient use of smaller gemological fragments. Further, as compared to placing fragments of crystalline material together using other techniques such as adhesive, the synthesis of crystalline material to join the plurality of fragments together to form the bulk object may impart improved strength and brilliance to the plurality of fragments joined to one another.

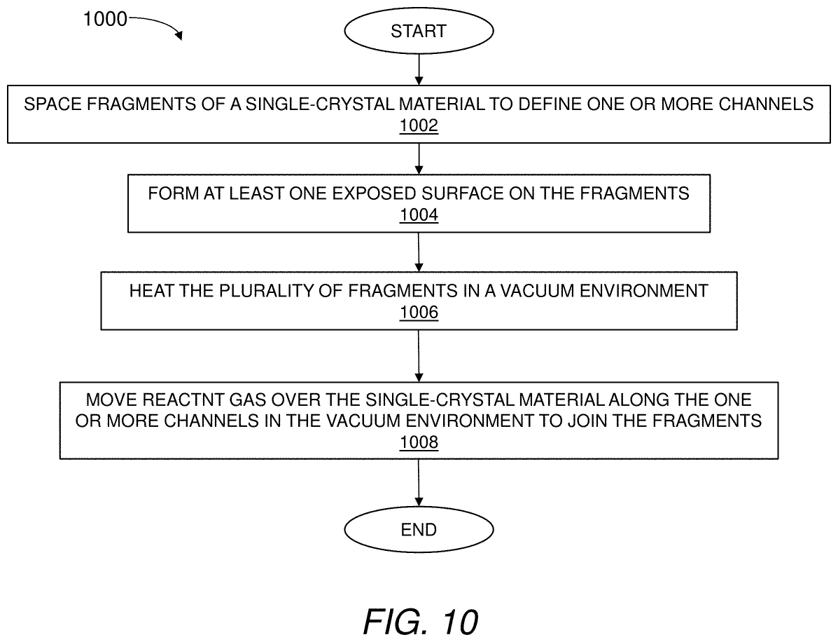

FIG. 10 is a flowchart of an exemplary method 1000 for forming a bulk object from a plurality of fragments. Unless otherwise specified or made clear from the context, the exemplary method 1000 may be implemented using any one or more of the various different systems, and components thereof, described herein. Thus, for example, one or more aspects of the exemplary method 1000 may be implemented as computer-readable instructions stored on the computer-readable storage medium 138 (FIG. 1A) and executable by the processing unit 136 (FIGS. 1A-1C) of the controller 106 (FIG. 1A) to operate the system 100 (FIG. 1A).

As shown in step 1002, the exemplary method 1000 may include, in a volume defined by a chamber, spacing a plurality of fragments of a single-crystal material (e.g., diamond) relative to one another to define one or more channels therebetween. Each fragment may be a naturally occurring instances of the single-crystal material or a synthesized instance of the single material (e.g., synthesized according to any one or more of the techniques described herein). As described in greater detail below, the single-crystal material may be synthesized along the one or more channels to hold the plurality of fragments together in the orientation initially set forth in spacing the plurality of fragments relative to one another.

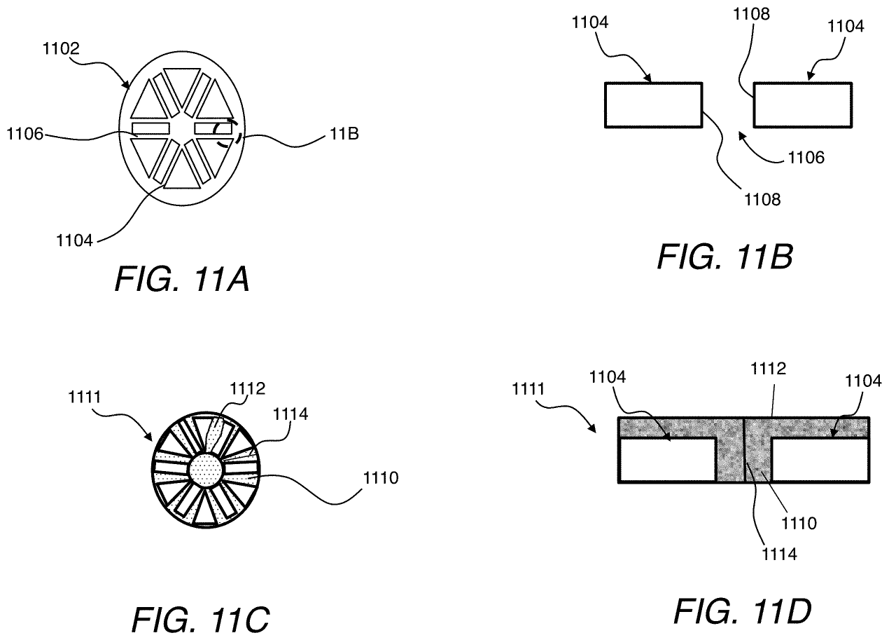

Referring now to FIGS. 11A and 11B, a fixture 1102 may support a plurality of fragments 1104 of a single-crystal material in a spaced apart configuration such that the plurality of fragments 1104 define one or more channels 1106 therebetween. The fragments 1104 act as the seed material 140 described above. It shall be understood that this arrangement of the plurality of fragments 1104 on the fixture 1102 may be, for example, the spacing in step 1002 of the exemplary method 1000 (FIG. 10). Thus, for example, the plurality of fragments 1104 of the single-crystal material may be placed in the fixture 1102 in a desired configuration relative to one another outside of a CVD reactor and then, with the plurality of fragments 1104 arranged in the spaced apart configuration on the fixture 1102, the assembly (i.e., the fixture 1102 supporting the fragments 1104) may be placed in a CVD reactor (e.g., the CVD reactor 104 in FIG. 1A).

In general, spacing the plurality of fragments 1104 relative to one another on the fixture 1102 may influenced by any one or more of various different aesthetic choices as well as considerations related to the time, cost, and physical constraints associated with synthesizing the single-crystal material along the spacing between the plurality of fragments 1104. In some implementations, therefore, spacing the plurality of fragments 1104 relative to one another may include orienting the plurality of fragments 1104 relative to one another according to a predetermined pattern of color variation in the plurality of fragments 1104.

To facilitate achieving a wide range of color variation beyond constraints of naturally sourced single-crystal material, at least some of the plurality of fragments 1104 may be synthesized, crystalline material (e.g., CVD diamond) including color variation attributable to doping with nitrogen, boron, or a combination thereof, according to any one or more of the various different techniques described herein. Thus, for example, the plurality of fragments 1104 may include two or more nitrogen-doped fragments (which are yellow), boron-doped fragments (which are blue), and undoped fragments (which are clear). The plurality of fragments 1104 may be spaced relative to one another such that two different color fragments are overgrown with CVD diamond to join them together into a single diamond gem having different color portions, as may be useful for achieving a particular appearance in the finished object. Further, or instead, at least some of the plurality of fragments 1104 having different levels of doping of the same color, as may be usefully arranged to provide a pattern of the intensity of a given color (e.g., a gem with more and less intense yellow colored portions) that may not be readily achievable using naturally sourced diamonds.

In certain implementations, spacing the plurality of fragments 1104 relative to one another on the fixture 1102 may also be based on constraints associated with synthesis (e.g., epitaxial growth) of the single-crystal material along the one or more channels 1106, using any one or more of the various different CVD processes described herein, to join the plurality of fragments 1104 together. Thus, for example, the plurality of fragments 1104 may be spaced relative to one another with crystal planes of the single-crystal material aligned with and parallel to one another. Without wishing to be bound by theory, it is believed that such alignment between adjacent instances of fragments of the plurality of fragments 1104 may facilitate robust synthesis of the single-crystal material (e.g., CVD diamond) along the one or more channels 1106. In turn, such robust synthesis of the single-crystal material along the one or more channels 1106 may result in improved structural integrity and/or appearance, as compared to spacings in which crystal planes are aligned in a different orientation.

Referring again to FIG. 10, as shown in step 1004, the exemplary method 1000 may include forming at least one exposed surface on each one of a plurality of fragments of the single-crystal material. Step 1004 may occur before or after step 1002. In this context, exposing a surface of the single-crystal material may include any carrying out any one or more of various different processes on the single-crystal material to increase exposure of the single-crystal material along the exposed surface, as compared to an exposure level of the single-crystal material along the exposed surface prior to the process used to expose the surface. Thus, for example, exposing a surface of the single-crystal material may include one or more of etching, polishing, or cutting the plurality of fragments to expose one or more surfaces of each of the plurality of fragments. Further, or instead, exposing a surface of the single-crystal material may include cleaning the surface to expose the single-crystal material.

Referring now to FIGS. 11A and 11B, at least one of the exposed surfaces 1108 of each of the plurality of fragments 1104 may be spaced relative to one another (e.g., facing one another) to define the one or more channels 1106 between the plurality of fragments 1104. As may be appreciated, positioning exposed surfaces 1108 along the one or more channels 1106 may advantageously promote synthesis along the one or more channels 1106 to join the plurality of fragments 1104 to one another (e.g., to form the bulk object, such as a gem). In certain instances, at least some of the exposed surfaces 1108 may be formed prior to spacing the plurality of fragments 1104 relative to one another on the fixture. Forming the exposed surfaces 1108 prior to spacing may, for example, facilitate achieving adequate exposure and/or tight dimensional tolerances (e.g., narrow widths of the one or more channels 1106). In some implementations, however, the exposed surfaces may further, or instead, be formed after the plurality of fragments 1104 are spaced relative to one another on the fixture 1102, as may be useful for increasing the likelihood that the one or more exposed surfaces 1108 are properly oriented to face one another along the one or more channels 1106.

Referring again to FIG. 10, as shown in step 1006, the exemplary method 1000 may include heating the plurality of fragments spaced relative to one another in a vacuum environment in the volume. Unless otherwise specified or made clear from the context, such heating may be carried out according to any one or more of the various different techniques described herein for heating within a volume under conditions in which crystalline material may be formed through CVD.

As shown in step 1008, the exemplary method 1000 may include moving a reactant gas over the single-crystal material along the one or more channels defined by the plurality of fragments heated in the vacuum environment in the volume. As the reactant gas moves along the one or more channels in the heated environment in the volume, one or more layers of the single-crystal material (e.g., CVD diamond) may be synthesized at least along the one or more channels to join the plurality of fragments to one another. In other words, CVD diamond material epitaxially overgrows the spaced apart diamond fragments 1104 to join the fragments 1104 into a single gem 1111.

Referring now to FIGS. 11C and 11D, a single-crystal material 1110 may be a synthetic diamond body synthesized according to the exemplary method 1000 (FIG. 10) to extend along the channels 1106 defined by the plurality of fragments 1104. For example, one of the fragments 1104 in FIG. 11D may comprise yellow colored nitrogen doped CVD diamond fragment, the other one of the fragments 1104 may comprise blue colored boron doped CVD diamond fragment, and the single-crystal material 1110 may comprise clear undoped epitaxially deposited CVD diamond material. In general, the single-crystal material 1110 synthesized along the one or more channels 1106 may join the plurality of fragments 1104 to one another to form a bulk object (e.g., gem) 1111. In certain implementations, the bulk object 1111 may be mosaic, having a predetermined appearance according to the relative positioning and properties of each fragment of the plurality of fragments 1104 and the single-crystal material 1110 synthesized along the one or more channels 1106.

The single-crystal material 1110 may be synthesized in two dimensions along the one or more channels 1106 defined by the spacing of the plurality of fragments 1104 (e.g., growing across the width of the one or more channels 1106 and along a length defined by the one or more channels 1106). Additionally, or alternatively, the single-crystal material 1110 may be synthesized to extend beyond the one or more channels 1106 in the vertical direction to form a bridge 1112 extending over at least a portion of the plurality of fragments 1104 joined by the single-crystal material 1110. The bridge 1112 may, among other things, facilitate imparting additional strength to the joining of the plurality of fragments 1104.

In certain instances, the plurality of fragments 1104 of the single-crystal material may be spaced relative to one another (e.g., according to step 1002 (FIG. 10) in a predetermined orientation to form a visible interface 1114 visible in the single-crystal material 1110 synthesized along the one or more channels 1106 to join the plurality of fragments 1104 to one another. The interface 114 may comprise a dislocation or another defect in the single-crystal material (e.g., CVD diamond) 1110. In this context, visibility of the interface 1114 may include perceptibility by unaided human vision, which shall be understood to be inclusive of human vision corrected normal acuity. The formation of the interface 1114 may be achieved, for example, by forming dislocations in the single-crystal material 1110 when portions that laterally grow in opposite directions from exposed surfaces of the fragments 1104 meet each other during along the one or more channels 1106. As may be appreciated, one or more of height and/or position of the interface 1114 may be controlled to form a portion of a visible part of the bulk object 1111.

E. Wearable Jewelry Including Modular Elements

Having described various different aspects of synthesizing crystalline material, attention is now directed to description of wearable jewelry including modular elements to facilitate customization of the look, style, type, and/or fit of jewelry by a wearer or designer. While it shall be appreciated that any one or more of the synthesis techniques discussed above may be suitable for fabricating any one or more of the various different modular elements of the of the wearable jewelry described below, other fabrication techniques may also, or instead, be used to fabricate modular elements, unless otherwise specified or made clear from the context. Thus, for example, to the extent any one or more of the various different aspects of wearable jewelry described herein may include crystalline material, such crystalline material shall be understood to include crystalline material synthesized according to any one or more of various techniques (e.g., such as any one or more of the synthesis techniques described herein) and/or naturally occurring crystalline material.

i. Modular Jewelry Systems

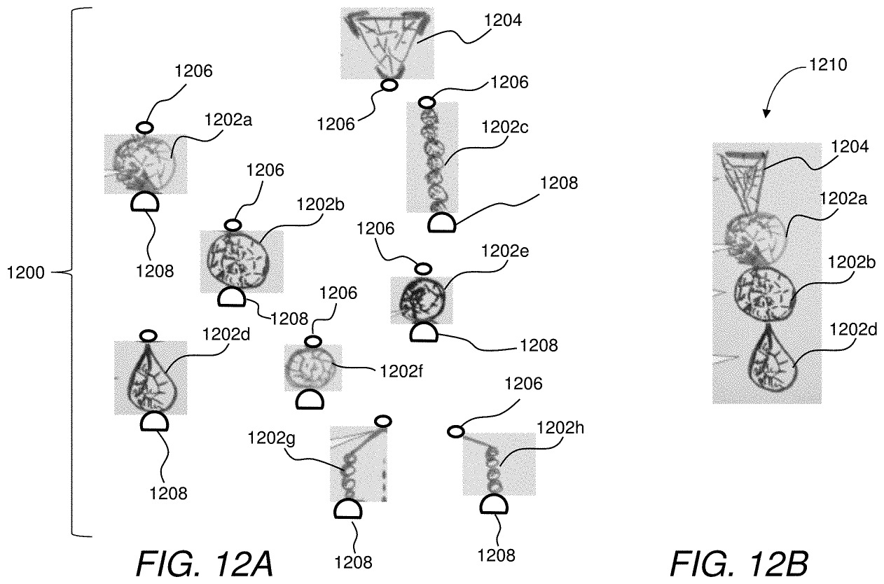

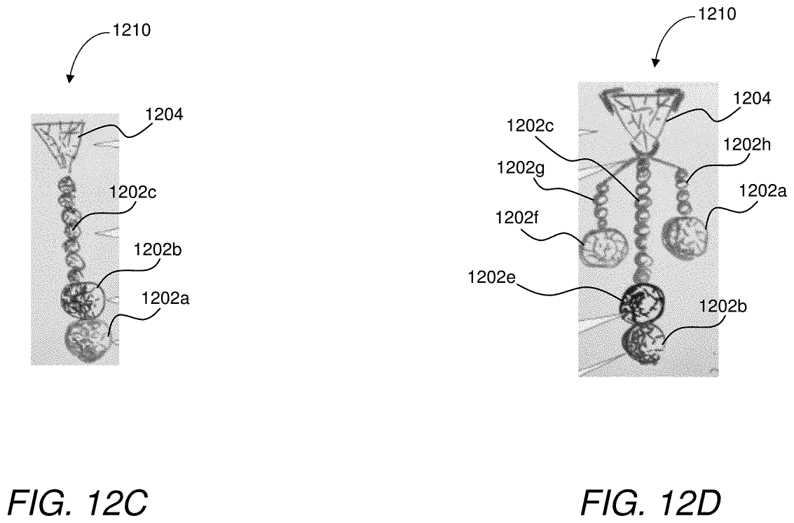

Referring now to FIGS. 12A-12D, a modular jewelry system 1200 may include ornaments 1202a,b,c,d,e,f,g,h (hereafter, collectively referred to as the ornaments 1202a-h and individually referred to as an ornament 1202a, ornament 1202b, ornament 1202c, ornament 1202d, ornament 1202e, ornament 1202f, ornament 1202g, and ornament 1202h, as applicable) and an attachment element 1204. Each of the ornaments 1202a-h may include a first fastening element 1206 and a second fastening element 1208, and the attachment element 1204 may be coupled to at least one of the ornaments 1202a-h. For the sake of clear and efficient explanation, the attachment element 1204 is illustrated as including the first fastening element 1206, although other arrangements of the attachment element 1204 with respect to the plurality of ornaments 1202a-h are additionally or alternatively possible. As described in greater detail below, the ornaments 1202a-h and the attachment element 1204 may be reconfigurable, without the use of tools, into any one or more of various different relative arrangements (e.g., arrangements including the attachment element 1204 and the full complement of the ornaments 1202a-h and/or arrangements including the attachment element 1204 and a subset of the ornaments 1202a-h) to facilitate customization of the modular jewelry system 1200 according to changing tastes and/or needs of the wearer.

In general, the first fastening element 1206 of each one of the ornaments 1202a-h may be releasably engageable in tool-free securement with the second fastening element 1208 of each other one of the ornaments 1202a-h in two or more configurations. As a specific example of engagement of the ornaments 1202a-h in two or more configurations, it shall be appreciated that the ornament 1202a and the ornament 1202b may be coupled to one another in a first configuration shown in FIG. 12A and in a second configuration FIG. 12B. Continuing with this example, because the first fastening element 1206 and the second fastening element 1208 are releasably engageable with one another in tool-free securement, the ornament 1202a and the ornament 1202b may be switched back and forth between the first configuration and the second configuration without the use of tools. That is, as used herein, tool-free securement shall be understood to include any manner and form of manual manipulation of one or both of the first fastening element 1206 and the second fastening element 1208 (e.g., a magnetic connection, a ball-and-socket arrangement, a hook-and-eye arrangement, or a combination thereof). Without the need to procure tools, such tool-free securement may facilitate, for example, changing configurations of the ornaments 1202a,b,c,d,e at any time desired or convenient for the wearer. Additionally, or alternatively, tool-free securement of the first fastening element 1206 and the second fastening element 1208 may be carried out without specialized skill, which may further or instead provide convenience to the wearer.

The attachment element 1204 and a plurality of the ornaments 1202a-h may collectively form a wearable jewelry accessory 1210. In general, the wearable jewelry accessory 1210 formable from the modular jewelry system 1200 may include any one or more of various different configurations of earrings, brooches, bracelets, anklets, necklaces, or other body-worn jewelry. Thus, to facilitate forming these different types of wearable jewelry, the wearable jewelry accessory 1210 may be releasably securable to a body of a wearer via tool-free securement of the attachment element 1204 to the first fastening element 1206 of each of the ornament 1202a-h, the second fastening element of each of the ornament 1202a-h, the body of the wearer, or a combination thereof.

In instances in which the wearable jewelry accessory 1210 is arranged as an earring, the attachment element 1204 may be manually operable in tool-free securement with an ear. The term “earring” used herein, however, is used herein in the broadest sense such that the term earring shall be understood to include any item of jewelry wearable in any body piercing. Thus, for example, to facilitate tool-free securement of the attachment element 1204 to form the wearable jewelry accessory 1210 as an earring securable to an ear or another body part of the wearer, the attachment element 1204 may include one or more of a wire or a stud movable through a piercing on the body of the wearer or a clip securable to the body of the wearer.

In instances in which the wearable jewelry accessory 1210 is arranged as a piece worn about a portion of the body of the wearer (e.g., a necklace, a bracelet, or an anklet), the wearable jewelry accessory 1210 may be arranged to be a shape enclosable about a body part of the wearer. In such instances, the attachment element 1204 and one or both of the first fastening element 1206 or the second fastening element 1208 of one of the ornaments 1202a-h may collectively form a clasp. That is, the attachment element 1204 coupled to one of ornaments 1202a-h may be releasably securable, via tool-free securement, to at least one of the first fastening element 1206 or the second fastening element 1208 of each other one of the ornaments 1202a-h to form the ornaments 1202a-h into the enclosed shape about a portion of the body of the wearer.

The ornaments 1202a-h may have any one of various different features as may be suitable for providing a degree of configurability of the wearable jewelry accessory 1210 useful to a wearer. Thus, in some instances, variation in configurations of the ornaments 1202a-h is achievable based at least upon variations in relative orientation of the ornaments 1202a-h to one another and/or to the attachment element 1204. As an example, the first fastening element 1206 of each one of ornaments 1202a-h may be releasably engageable in tool-free securement with the second fastening element 1208 of more than one of the other instances of the ornaments 1202a-h in a branching arrangement of the plurality of ornaments 1202a-h. Additionally, or alternatively, the attachment element 1204 may be releasably engageable in tool-free securement with the first fastening element 1206 and/or the second fastening element 1208 of more than one of the ornaments 1202a-h to form a branching arrangement, cascading from the attachment element 1204, an example of which is shown in FIG. 12D.

While variation in configurations of the wearable jewelry accessory 1210 may be achieved through variations in relative orientations of the ornaments 1202a-h to one another and/or to the attachment element 1204, variations in one or more properties among the ornaments 1202a-h may provide additional, or alternative, degrees of variability that may be imparted to the wearable jewelry accessory 1210. For example, each of the ornaments 1202a-h may have a different shape (e.g., gems with different cuts, or multiple gems on the same ornament), a different color, different indicia, different material composition (e.g., metal, ceramic, or plastic), or a combination thereof relative to at least another one of the ornaments 1202a-h. Additionally, or alternatively, one or more of the ornaments 1202a-h may be chain elements that may be attachable to one another and/or to the attachment element 1204 and, in some cases, the attachment element 1204 may include a chain element (e.g., one or more of a metal chain or a stone setting in the form of a chain) connectable to one or more of the ornaments 1202a-h. Chain elements in the ornaments 1202a-h and/or the attachment element 1204 may facilitate, for example, forming the wearable jewelry accessory 1210 with a plurality of different branching arrangements, such as branching arrangements cascading in a direction away from the attachment element 1204 and/or branching arrangements converging in a direction away from the attachment element 1204.

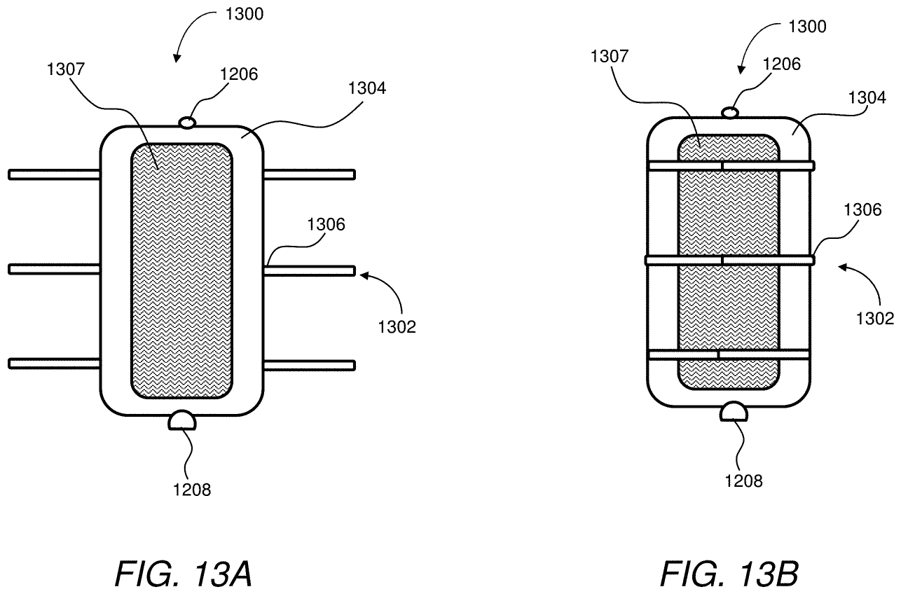

Referring now to FIGS. 13A and 13B, an ornament 1300 may include a cage 1302 defining a setting 1304. A portion 1306 of the cage 1302 may be movable to a first position (FIG. 13A) to receive a stone 1307 (e.g., a bulk object including synthesized crystalline material formed according to any one or more of the various different techniques described herein, naturally occurring gems, naturally occurring non-gemological stones, or a combination thereof). Further, or instead, the portion 1306 of the cage 1302 may be movable to a second position (FIG. 13B) overlapping the stone 1307 to hold the stone 1307 in place in the setting 1304. Unless otherwise specified or made clear from the context, it shall be understood that the ornament 1300 may be compatible with the ornaments 1202a-h (FIG. 12A) such that the ornament 1300 may be used in place of or in addition to any one or more of the ornaments 1202a-h (FIG. 12A) to form the wearable jewelry accessory 1210 (FIG. 12B-12D) with gems that may be readily replaced to change, among other things, aspects of the appearance of the wearable jewelry accessory 1210 (FIG. 12B-12D). Thus, the ornament 1300 shall be further understood to include the same fastening elements as each of the ornaments 1202a-h (FIG. 12A) and, for the sake of efficient description, these are not described separately for the ornament 1300.

ii Modular Ring Systems

While the modular jewelry systems described above may be formed in enclosed shapes that include rings, modular ring systems are described separately below to highlight certain aspects of modular jewelry systems that may be unique to the formation of rings or, to the extent applicable to other form factors of jewelry, may be particularly clearly described in the context of rings, as compared to other types of jewelry. Accordingly, unless a contrary intent is explicitly specified or made clear from the context, the features of modular ring systems described below shall be understood to be substantially useable in addition to or interchangeably with any one or more of the features described with respect to the modular jewelry systems described above.

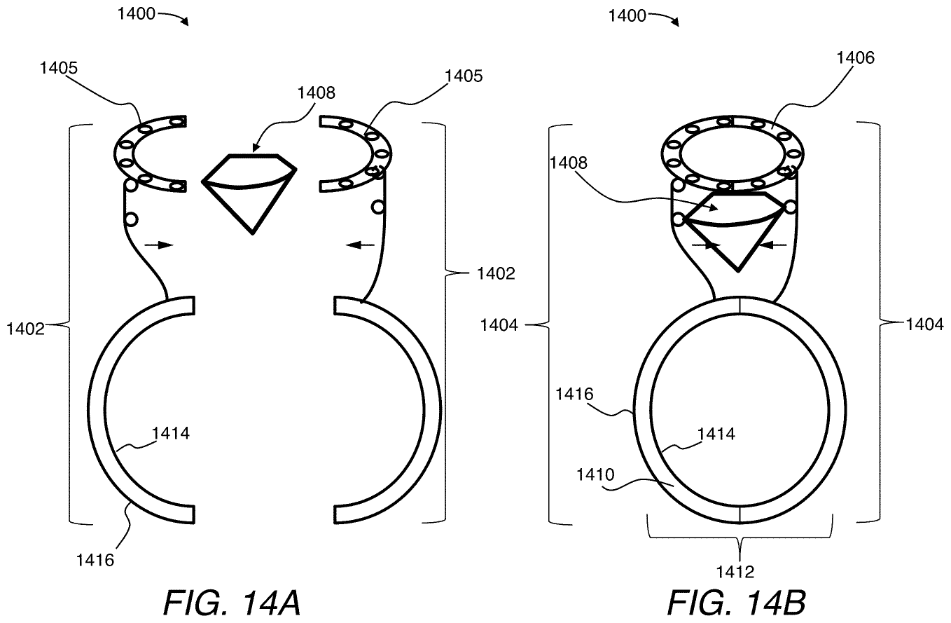

Referring now to FIGS. 14A and 14B, a modular ring system 1400 may include a first section 1402 and a second section 1404. The first section 1402 of the modular ring system 1400 may include at least one portion 1405 of a gallery 1406 and an ornament 1408 disposed the at least one portion 1405 of the gallery 1406 included in the first section 1402. The second section 1404 of the modular ring system 1400 may, in some instances, include at least one portion of a band 1410. In general, the first section 1402 and the second section 1404 may be releasably engageable with one another to collectively form a ring 1412 including the band 1410 and the gallery 1406, with the band 1410 of the ring 1412 having an inner surface 1414 and an outer surface 1416 opposite the inner surface 1414. The inner surface 1414 of the band 1410 may circumscribe a digit (e.g., a finger or a toe) of the wearer of the ring 1412. That is, with the ring 1412 worn on the digit of the wearer, the inner surface 1414 of the band 1410 may be in contact with the digit of the wearer to facilitate, for example, holding the ring 1412 substantially in place on the digit of the wearer. Further, or instead, with the ring 1412 worn on the digit of the wearer, the ornament 1408 along the gallery 1406 may be at least partially exposed in a direction away from the outer surface 1416 of the band 1410, as may be useful for displaying the ornament 1408 while the ring 1412 is worn by the wearer. In some instances, interchangeability of different instances of the first section 1402 with different instances of the second section 1404 may facilitate forming the ring 1412 according to various different specifications, such as may be useful for changing one or more of the size or appearance of the ring 1412 without the use of tools or specialized skill.

In general, the first section 1402 and the second section 1404 may be releasably engageable with one another in any one or more of various different arrangements as may be useful for maintaining the shape of the ring 1412 at least while the ring 1412 is worn on the digit of the wearer. Thus, for example, the first section 1402 and the second section 1404 may be releasably engageable with one another in a snap-fit arrangement. Additionally, or alternatively, the first section 1402 and the second section 1404 may be releasably engageable with one another along the inner surface 1414 of the band 1410 collectively formed by the first section 1402 and the second section 1404 such that, in some instances, the digit of the wearer may hold the first section 1402 and the second section 1404 together in releasable engagement. In some implementations, the first section 1402 and the second section 1404 may be releasably engageable with one another along the outer surface 1416 of the band 1410 (e.g., along one or both sides of the gallery 1406) collectively formed by the first section 1402 and the second section 1404, which may facilitate switching one or more of the first section 1402 and the second section 1404 while the ring 1412 is worn on the digit.

While certain aspects of forming modular ring systems with variable appearances have been described, other techniques for altering the appearance of the modular ring systems are additionally, or alternatively, possible. For example, in certain instances, the gallery 1406 may be entirely defined by the at least one portion 1405 of the first section 1402, it shall be appreciated that the second section 1404 may define another portion of the gallery 1406 in some implementations. That is, continuing with this example, the first section 1402 and the second section 1404 may be releasably engageable with one another such that the first section 1402 and the second section 1404 collectively form the gallery 1406 holding the ornament 1408 in a fixed position between the first section 1402 and the second section 1404 with the band 1410 circumscribed about the digit of the wearer.

As another example, while variations in modular ring systems have been described as having a first section and a second section that may be changed to form different appearances, it shall be appreciated that modular ring systems of the present disclosure may include additional sections (e.g., three, four, five, etc.), as may be useful for achieving a useful number of options for varying appearance of rings formable from the modular ring systems described herein. Further, or instead, to facilitate achieving variation in appearance with the most efficient use of discrete sections, the ornament 1408 in the modular ring system 1400 may be securable along the gallery 1406 by a cage to restrict movement of the ornament 1408 at least in a direction away from the outer surface 1416 of the band 1410. The cage 1302 (FIG. 13) described above with respect to the ornament 1300 (FIG. 13) is an example of such a cage. That is, the ornament 1408 may be removed from a cage and replaced with a different ornament or ornaments (e.g., in a manner analogous to the replacement of the ornament 1300 described above with respect to FIG. 13) to facilitate changing the appearance of the ring 1412. In implementations associated with a ring, it shall be appreciated that the cage, such as the cage 1302 (FIG. 13), may restrict movement of the ornament 1408 at least from the outer surface 1416 in a direction away from the band 1410. In some instances, the digit of the wearer of the ring 1412 may restrict movement of the ornament 1408 from the inner surface 1414 in a direction away from the band 1410.

F. Wearable Jewelry with Dynamic Variability

Having described various different approaches to customizing the appearance of wearable jewelry based on static arrangements of elements of various modular systems, other approaches to customization of the appearance of wearable jewelry are additionally, or alternatively, possible. In particular, as described in greater detail below, certain implementations wearable jewelry may include dynamically variable appearance. As used in this context, dynamic variations in the appearance of an item of wearable jewelry shall be understood to include a range of changes in appearance of the item of wearable jewelry that: a) are achievable while the item is worn by a wearer; b) achievable without changing connections between portions of the elements of the item of jewelry; and c) extend beyond a range of changes in appearance associated with unaltered reflection of light from the item of jewelry. Thus, as described in greater detail below, dynamic variations in the appearance of an item of wearable jewelry shall be understood to include one or more of powered movement of at least a portion of a wearable item of jewelry, powered illumination of at least a portion of a wearable item of jewelry, or powered or passive augmentation of illumination of at least a portion of a wearable item of jewelry through incident light directed through light pipes.

The various different aspects of dynamic variation of wearable jewelry described below have been described separately from static variations of wearable jewelry for the sake of clear and efficient description. Unless explicitly noted or made clear from the context, any one or more of the dynamic variations of wearable jewelry described below shall be understood to be interchangeably with, or in addition to, any one or more of the jewelry systems described above with respect to wearable jewelry systems including modular elements. Thus, as a specific example, any one or more of the ornaments described below as including dynamic variability shall be understood to be compatible with the ornaments 1202a-h (FIG. 12A) such that the respective ornament with dynamic variability may be used in place of or in addition to any one or more of the ornaments 1202a-h (FIG. 12A) to form the wearable jewelry accessory 1210 (FIGS. 12B-12D) with dynamic enhancements, such as lighting and/or motion. Accordingly, any one or more of the ornaments described below as including dynamic variability shall be understood to include the same fastening elements as each of the ornaments 1202a-h and, for the sake of efficient description, these are not described separately for the respective ornament having dynamic variability. Analogous interchangeability shall be understood with respect to any one or more of the ornaments described below as including dynamic variability and the ornament 1300 (FIG. 13) and the modular ring system 1400 (FIGS. 14A and 14B).

i. Wearable Jewelry with Dynamic Motion

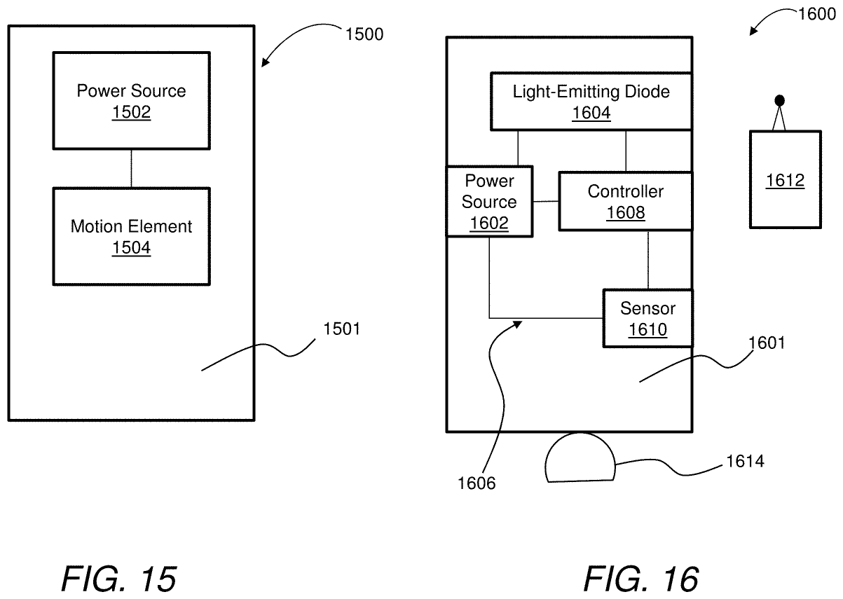

Referring now to FIG. 15, a system 1500 may include a power source 1502 (e.g., one or more of a single-use battery, a rechargeable battery an ultracapacitor, a solar panel, or a micro-motion generator) and a motion element 1504 in electrical communication with the power source 1502. The power source 1502 and the motion element 1504 may each be carried along an ornament 1501. The motion element 1506 may be operable, for example, to move the ornament 1501 through one or more of rotation or vibration. Movement of the ornament 1501 may be useful, for example, for drawing attention to the placement of the ornament 1501 relative to other ornaments in any one or more arrangements of ornaments described herein. The motion element 1504 may be, for example, one or more of a piezoelectric element, an ultracapacitor, a micro-motion generator, or a solar-powered motor. More generally, the motion element 1504 may transmit motion to the ornament 1501 through efficient use of both energy and space to facilitate forming the system 1500 within a size envelope suitable as wearable jewelry.

ii. Wearable Jewelry with Dynamic Illumination

Referring now to FIG. 16, a system 1600 may include a power source 1602 and a light-emitting diode 1604, each carried along (e.g., in, on, or a combination thereof) an ornament 1601. The power source 1602 may be any one or more of the power sources described above with respect to the power source 1502 (FIG. 15) and, thus for example, may include any one or more of various different rechargeable batteries to facilitate reusability of the ornament 1601. The ornament 1601 may include a gasketed seal on all closing surfaces to reduce the likelihood of water ingress into the ornament. In instances in which the ornament 1601 includes connectors, such connectors may be IP rated to reduce the likelihood that water may interfere with use of the ornament 1601 as an illumination source.

The light-emitting diode 1604 may be a single semiconductor light source or an array of semiconductor light sources (e.g., operable as one, individually, or as subsets of one another). Thus, unless a contrary intent is indicated or made clear from the context, references to the light-emitting diode 1604 shall be understood as being inclusive of a single light-emitting diode or a plurality of light-emitting diodes and, for the sake of efficiency, such variations in number are not described separately. Thus, by way of example and not limitation, light produced by the light-emitting diode 1604 may have any one or more of the following properties: a single color on the visible spectrum; a plurality of colors on the visible spectrum; light emission corresponding to light emission corresponding to at least one predetermined wavelength as may be useful for generating a response from a gem on or in proximity to the ornament 1601).

In some instances, at least a portion of the ornament 1601 may be diamond that forms at least a portion of the semiconductor material of the light-emitting diode 1604. That is, in instances in which the ornament 1601 includes a displayed diamond, the light-emitting diode 1604 may be integrated with the diamond. Integration of the light-emitting diode 1604 with the diamond material of the ornament 1601 may be useful, for example, for forming the ornament 1601 within a specific size envelope.

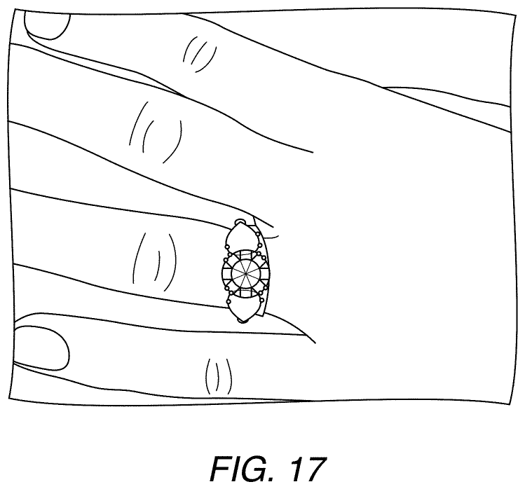

Referring now to FIGS. 16 and 17, at least a portion of the ornament 1601 may be gemological material, and the light-emitting diode 1604 may emit light of a wavelength at which the gemological material has a fluorescent response. For example, as shown, the light-emitting diode 1604 may emit long-wave ultraviolet light (also known as “black light”) to generate a fluorescent response in a pink sapphire. Additionally, or alternatively, the light-emitting diode 1604 may be controllable to alternate between emitting a first color absorbable by the gemological material and a second color transmittable by the gemological material.

Collectively, the power source 1602 and the light-emitting diode 1604 may form at least a portion of a circuit 1606 carried along ornament 1601, along which the power source 1602 and the light-emitting diode 1604 are connectable into electrical communication with one another such that the light-emitting diode 1604 may generate light directed in any one or more of various different directions, patterns, colors, or combinations thereof useful for creating a desired aesthetic impression at the ornament 1601 itself or at another portion (e.g., a gem) of a wearable jewelry item. Additionally, or alternatively, it should be appreciated that the circuit 1606 may include any one or more of various other elements as may be useful for robust operation of the circuit 1606 to deliver power from the power source 1602 to the light-emitting diode 1604. Examples of such other elements include, but are not limited to, the following: an isolator to prevent operation of the circuit 1606 until the isolator is removed to facilitate shipping the ornament 1601; current limiting resistors; fusing that short-circuits the circuit 1606 in the event of component malfunction; an on-off switch to allow the wearer to determine whether the light-emitting diode 1604 is on and when it is off in challenging light conditions; a connector to an external circuit for charging the power source 1602; an alignment element to facilitate inductive coupling to an external circuit for charging the power source 1602.

The circuit 1606 may further include a controller 1608 in electrical communication with the light-emitting diode 1604 and carried along the ornament 1601. The controller 1608 may control any one or more of various different aspects of the light-emitting diode 1604 as may be useful for generating a light-pattern suitable for any one or more of the various different implementations described herein. As an example, the controller 1608 may control the light-emitting diode 1604 to change color randomly and/or through a predetermined cycle (e.g., a color wheel progression).

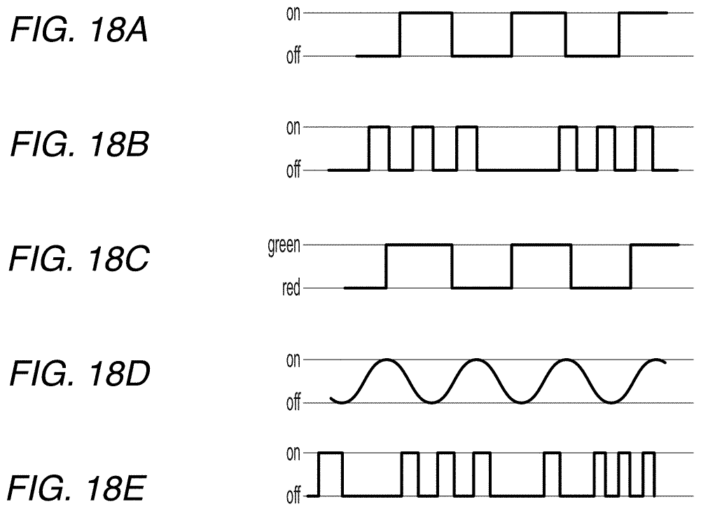

As an additional or alternative example, referring now to FIG. 16 and FIGS. 18A-18E, the controller 1608 may control the light-emitting diode 1604 according to any one or more of various different duty cycles. As used in this context, the term “duty cycle” shall be understood to include any one or more of various different predetermined cycle of an on/off state of the light-emitting diode 1604, one or more of various different cycles between two colors of the light-emitting diode 1604, or a combination thereof. Thus, for example, the controller 1608 may control the on/off state of the light-emitting diode 1604 according to a predetermined cycle of step-changes associated with blinking (FIG. 18A). Further, or instead, the controller 1608 may control the on/off state of the light-emitting diode 1604 according to a predetermined cycle of step-changes including fast pulses and long periods of off time (FIG. 18B). Additionally, or alternatively, the controller 1608 may control color of the light-emitting diode 1604 according to a predetermined cycle of step-changes between green and red (FIG. 18C). Still further or instead, the controller 1608 may control the on/off state of the light-emitting diode 1604 according to a predetermined cycle of sinusoidal (or other gradual) variation (FIG. 18D). While a sinusoid is an example of gradual change that may be imparted to one or more parameters of the light-emitting diode 1604, other gradual variations may additionally or alternatively be used. For example, a duty cycle of the light-emitting diode 1604 may be pulsed to increase gradually in intensity and decrease gradually in intensity, with a spike of intensity introduced between these gradual increases and decreases such that the light-emitting diode 1604 generates a light pattern similar to a natural sparkle of light (e.g., from ripples of water struck by sunlight or moonlight). As may be appreciated, the foregoing variations are exemplary and other variations are additionally, or alternatively possible. Thus, in instances in which a duty-cycle has been described in terms of on-off states of the light-emitting diode 1604, it shall be understood that the same or similar duty cycles may be carried out in terms of variations of color and/or brightness of the light-emitting diode 1604, and vice versa.

Referring now to FIG. 16 and FIG. 18E, the system 1600 may further, or instead, include a sensor 1610 carried along the ornament 1601 in electrical communication with the controller 1608. The controller 1608 may control the light-emitting diode 1604 (e.g., one or more of the color, brightness, or on/off state of the light-emitting diode 1604) based at least in part on a signal received from the sensor 1610. As an example, the sensor 1610 may include a microphone, and the controller 1608 may control the on/off state (or one or more other variables) of the light-emitting diode 1604 based on pulses of noise (e.g., the beat of music) detected by the sensor 1610 (FIG. 18E).

Referring again to FIG. 16, while the foregoing example is based on the sensor 1610 being a microphone, it shall be appreciated that the sensor 1610 may be any one or more of various different types of input devices, such as may be useful as an input for controlling the light-emitting diode 1604. In some instances, therefore, the sensor 1610 may sense input from a user (e.g., sensing actuation physical depression of a button, capacitive touch sensing, a switch) to change a function of the light-emitting diode 1604 (e.g., changing from a solid light to a blinking light upon depressing the button). That is, more generally, the light-emitting diode 1604 may be user-programmable (e.g., according to a user-defined color scheme) based on one or more inputs received through the sensor 1610.

In other instances, the sensor 1610 may sense one or more parameters in the vicinity of the ornament 1601, such as may be useful for adjusting the light-emitting diode 1604 in response to an environmental condition, a condition of the wearer, or a combination thereof. As an example, the sensor 1610 may include a light detector, and the controller 1608 may control the light-emitting diode 1604 according to light detected by the sensor 1610 based on light detected by the sensor 1610 in the vicinity of the ornament 1601, as may be useful for adjusting light transmitted by the light-emitting diode 1604 according to detected ambient light conditions. As an additional or alternative example, the sensor 1610 may include a thermal sensor, and the controller 1608 may control the light-emitting diode 1604 according to temperature detected by the sensor 1610 based on temperature detected by the sensor in the vicinity of the ornament 1601 or temperature detected on skin of the wearer, as may be useful for providing the wearer with a visual indication of temperature while wearing the ornament 1601. Further, or instead, the sensor 1610 may include a clock, and the controller 1608 may control the light-emitting diode 1604 according to time, as may be useful for changing illumination of the light-emitting diode 1604 according to a schedule of the user (e.g., gradually increasing in brightness around dusk and turning off after a predetermined time at night, using a color scheme based on calendar dates, etc.). Still further, or instead, the sensor 1610 may include a moisture sensor, as may be useful for detecting moisture conditions (e.g., submersion) that may be likely to damage a portion of the ornament 1601 and, in some cases, serve as an input to the controller 1608 to cause the power source 1602 to complete functions to protect the ornament 1601 or change functions in the presence of water. In some cases in which the sensor 1610 includes a moisture sensor, the sensor 1610 may detect perspiration on skin of the wearer and may change one or more functions of the light-emitting diode 1604 based on the detected perspiration. Further or instead, the sensor 1610 may include an accelerometer, and detection of a particular motion (e.g., a wave or shake) serving as an input to the controller 1608 to change one or more functions of the light-emitting diode 1604. In some instances, the sensor 1610 may include a heartrate monitor, and the one or more functions of the light-emitting diode 1604 may be changed based on the measured heartbeat of the wearer (e.g., pulsing the light-emitting diode 1604 according to the measured heartbeat).

In some implementations, the sensor 1610 may provide one or more location signals to the controller 1608 control one or more parameters of the light-emitting diode 1604. For example, the sensor 1610 may include a location signal, and one or more parameters of the light-emitting diode 1604 may vary based on the location signal (e.g., reflecting colors of sports teams at sports event locations). Additionally, or alternatively, the one or more location signals sensed by the sensor 1610 may reflect proximity of the ornament 1601 to other instances of the ornament 1601 worn by other wearers. That is, continuing with this example, the light-emitting diode 1604 may create a color or blinking pattern relative to the respective color and/or blinking pattern of light-emitting diodes of instances of the ornament 1601 detected as being nearby. In some cases, the colors and/or blinking patterns may be controlled to match one another, contrast one another (e.g., to change light emissions to create a “wave” pattern), or a combination thereof.

Further, or instead, the sensor 1610 may include a wireless signal transceiver, and the controller 1608 may control the light-emitting diode 1604 based on the wireless signal detected by the sensor 1610, as may be useful for controlling illumination of the ornament 1601 using a smart device 1612 in communication with the ornament 1601 via sensor 1610. The communication between the smart device 1612 and the ornament 1601 may include short range communication (e.g., via Bluetooth®) and/or communication over a data network.

The smart device 1612 may be, for example, a smart phone or a smart TV having stored thereon an application responsive to external signals to send a command to the controller 1608 to control the light-emitting diode 1604 based on the external signals received by the smart device 1612. Examples of the external signals received by the smart device 1612 and used as a basis for controlling the light-emitting diode 1604 include one or more of the following: a synchronization signal associated with a location (e.g., a stadium); a signal indicating that a predetermined sports team scored; events related to a broadcast, a signal associated with a portion of a building.

In some instances, the light emission from the light-emitting diode 1604 may be transmitted to the smart device such that the smart device 1612 may reflect the color scheme of the light-emitting diode 1604 when the ornament 1601 is in proximity to the smart device 1612. For example, the smart device 1612 may include smart lights that change based on the light emitted from the light-emitting diode 1604 as the ornament 1601 is brought into proximity with the smart device 1612. As a more specific example, the signal sent from the sensor 1610 to the smart device 1612 may include information regarding light emitted by the light-emitting diode 1604 of the ornament 1601 and, based on the signal received from the sensor 1610, the smart lights of the smart device 1612 may change to match the light emitted by the light-emitting diode 1604 of the ornament 1601.

In certain implementations, the ornament 1601 may include a fastener 1614 securable to a wearer. The fastener 1614 may be, for example, a clip or a pin that may be secured to an article of clothing of a wearer without damaging the article of clothing. Additionally, or alternatively, the fastener 1614 may be generally reusable such that the ornament 1601 may be used like a brooch, and transferred to different articles of clothing as may be desired by the wearer.

While certain features of dynamic illumination have been described, other aspects of dynamic illumination are additionally or alternatively possible.

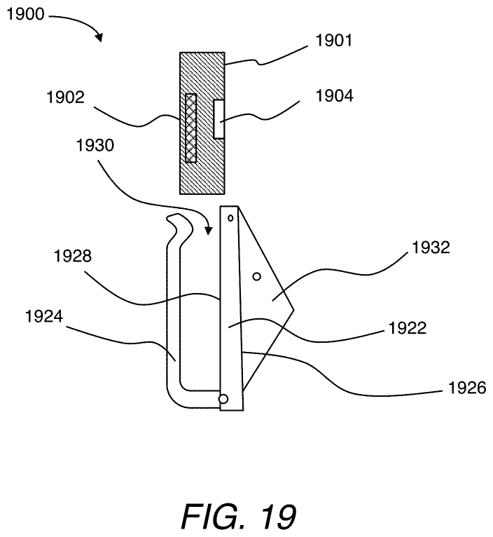

As an example, while dynamically illuminable ornaments (e.g., the ornament 1601) have been described as being fastenable to an article of clothing of a wearer and usable on its own as a customizable item of jewelry, other types of securement of dynamically illuminable ornaments are additionally or alternatively possible. For example, referring now to FIG. 19, a system 1900 may include a power source 1902 and a light-emitting diode 1904 carried along an ornament 1901. For the sake of clear and efficient description, elements of the system 1900 shall be understood to be analogous to or interchangeable with elements corresponding to 1600-series element numbers (e.g., in FIG. 16) described herein, unless otherwise explicitly made clear from the context and, therefore, are not described separately from counterpart 1600-series element numbers, except to note differences or emphasize certain features. Thus, for example, the power source 1902 shall be understood to be analogous to the power source 1602 (FIG. 16), the light-emitting diode 1904 shall be understood to be analogous to the light-emitting diode 1604 (FIG. 16), and the ornament 1901 shall be understood to be analogous to the ornament 1601 (FIG. 16).

In certain implementations, the system 1900 may include a clip 1920 having a bezel 1922 and a spring portion 1924. In general, the bezel 1922 may have a first side 1926 and a second side 1928 opposite the first side 1926. The spring portion 1924 may be coupled to the bezel 1922 and biased into contact with the first side 1926 of the bezel 1922. The spring portion 1924 may be flexible in a direction away from the first side 1926 of the bezel 1922 to form a recess 1930 into which the ornament 1901 (carrying the power source 1902 and the light-emitting diode 1904) is positionable. With the ornament 1901 positioned in the recess 1930, bias of the spring portion 1924 toward the first side 1926 of the bezel 1922 may hold the ornament 1901 with the light-emitting diode 1904 facing the first side 1926 of the bezel 1922.

In use, a gem 1932 may be supported on the second side 1928 of the bezel 1922. The light-emitting diode 1904 held in place against the first side 1926 of the bezel 1922 by force of the spring portion 1924 on the ornament 1901 may be actuated according to any one or more of the various different techniques described herein to illuminate the gem 1932.

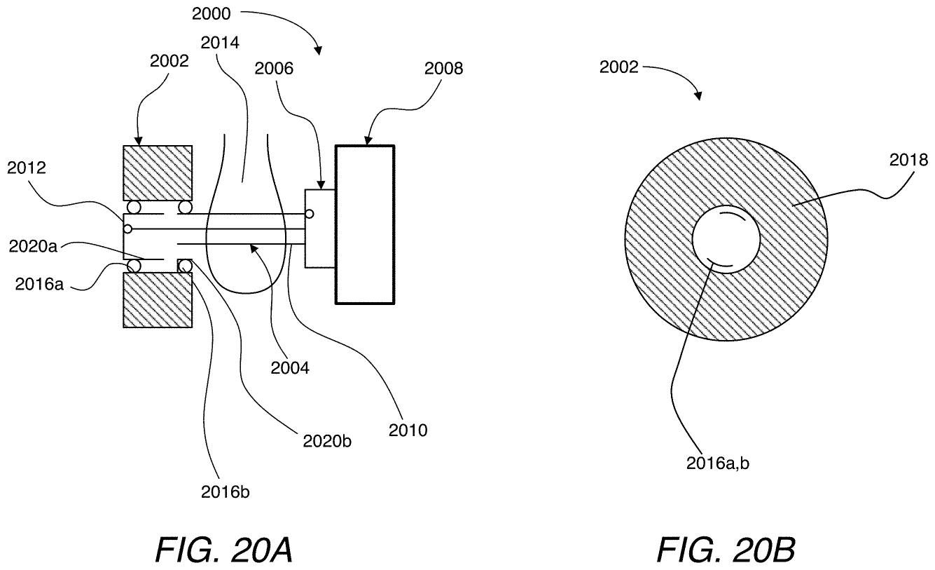

As another example, while dynamically illuminable ornaments have been described as being fastenable to an article of clothing of a wearer or to a gem or other structure of an article of jewelry, dynamically illuminable ornaments may be additionally or alternatively integrated into an article of jewelry. For example, referring now to FIGS. 20A and 20B, a system 2000 may include a battery 2002, a post 2004, a light-emitting diode 2006, and an ornament 2008. In general, the ornament 2008 may be any one or more of the various different ornaments described herein and, further or instead, may be illuminable by the light-emitting diode 2006. The light-emitting diode 2006 and the ornament 2008 may each be coupled to a first end region 2010 of the post 2004 (e.g., the ornament 2008 may be coupled to the first end region 2010 of the post 2004 via the light-emitting diode 2006), and the battery 2002 may be releasably securable to a second end region 2012 of the post 2004. For example, the second end region 2012 of the post 2004 may be movable through a piercing of an earlobe 2014 of a wearer. With the post 2004 extending through the earlobe 2014, the battery 2002 may be secured to the second end region 2012 of the post 2004 to hold the system 2000 in place on the earlobe 2014 of the wearer. In certain instances, securement of the battery 2002 to the second end region 2012 of the post 2004 may, further or instead, establish electrical communication between the battery 2002 and the light-emitting diode 2006 via the post 2004. As an example, the battery 2002 may include first contacts 2016a,b disposed along a body region 218 of the battery 2002, and the second end region 2012 of the post may include second contacts 2020a,b in electrical communication with the light-emitting diode 2006 along the first end region 2010 of the post 2004. Continuing with this example, then, securement of the battery 2002 to the second end region 2012 of the post may establish contact between the first contacts 2016a,b and second contacts 2020a,b to provide power from the battery 2002 to the light-emitting diode 2006. The first contacts 2016a,b may be, for example, spring contacts to facilitate securement of the battery 2002 to the second end region 2012 of the post 2004. In some implementations, the battery 2002 may be rotatable relative to the second end region 2012 of the post 2004 to interrupt connection between the first contacts 2016a,b and the second contacts 2020a,b and, thus, turn the light-emitting diode 2006 on and off. Further, or instead, it may be appreciated that, once depleted, the battery 2002 may be removed from the second end region 2012 of the post 2004 and replaced with a new instance of the battery 2002, as needed for providing power to the light-emitting diode 2006. In certain implementations, the system 2000 may include insulating material (e.g., ceramic) along the post 2004 or any other portion of the system 2000 in contact with the earlobe 2014 of the wearer, as may be useful for reducing the amount of heat transferred from the system 2000 to the wearer. Further, or instead, while the circuit formed by the battery 2002 and the light-emitting diode 2006 is shown as having two poles, it shall be appreciated that this circuit may have additional poles to bring logic to the light-emitting diode 2006, as may be useful in certain implementations. Still further or instead, the system 2000 may include fuses as necessary to reduce the likelihood of an over-current condition in the vicinity of tissue of the wearer.

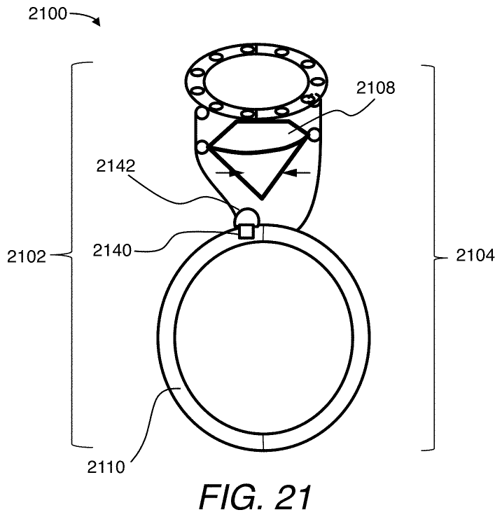

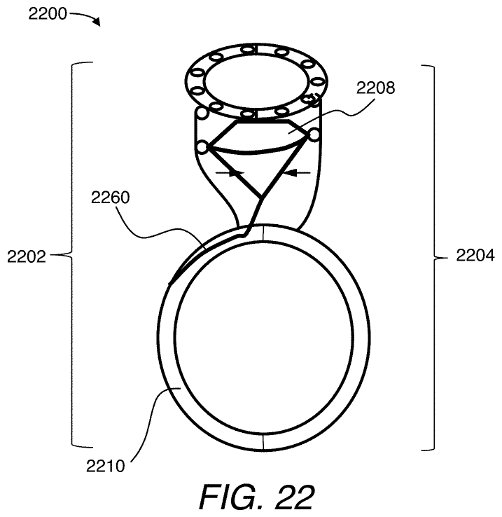

As yet another, referring now to FIG. 21, a modular ring system 2100 may include a first section 2102, a second section 2104, and an ornament 2108. For the sake of clear and efficient description, elements of the modular ring system 2100 shall be understood to be analogous to or interchangeable with elements corresponding to 1400-series element numbers (e.g., in FIGS. 14A and 14B) described herein, unless otherwise explicitly made clear from the context and, therefore, are not described separately from counterpart 1400-series element numbers, except to note differences or emphasize certain features. Thus, for example, the first section 2102 shall be understood to be analogous to the first section 1402 (FIGS. 14A and 14B), the second section 2104 shall be understood to be analogous to the second section 1404 (FIGS. 14A and 14B). Further, or instead, the ornament 2108 shall be understood to be analogous to the ornament 1408 (FIGS. 14A and 14B) and, in the context of the modular ring system 2100, shall be generally understood as the portion of the modular ring system 2100 dynamically illuminated.

The modular ring system 2100 may additionally include a power source 2140 and a light-emitting diode 2142. In general, the power source 2140 shall be understood to be analogous to any one or more of the various different power sources described herein with respect to dynamic illumination of jewelry, and the light-emitting diode 2142 shall be understood to be analogous to any one or more of the various different light-emitting diodes described herein with respect to dynamic illumination of jewelry. Thus, more specifically, the power source 2140 shall be understood to be analogous to the power source 1602 (FIG. 16), and the light-emitting diode shall be understood to be analogous to the light-emitting diode 1604 (FIG. 16), unless otherwise specified or made clear from the context. The light-emitting diode 2142 may be disposed along one or both of the first section 2102 or the second section 2104 of the modular ring system 2100. However, for the sake of illustration, the light-emitting diode 2142 is shown as disposed along the first section 2102. In general, the light-emitting diode 2142 may be directed toward the ornament 2108 to illuminate the ornament 2108 at least when a band 2110 formed by the first section 2102 and the second section 2104 is circumscribed about the digit of the wearer.

As still another example, a modular ring system 2200 may include a first section 2202, a second section 2204, and an ornament 2208. For the sake of clear and efficient description, elements of the modular ring system 2200 shall be understood to be analogous to or interchangeable with elements corresponding to 1400-series element numbers (e.g., in FIGS. 14A and 14B) described herein, unless otherwise explicitly made clear from the context and, therefore, are not described separately from counterpart 1400-series element numbers, except to note differences or emphasize certain features. Thus, for example, the first section 2202 shall be understood to be analogous to the first section 1402 (FIGS. 14A and 14B), the second section 2204 shall be understood to be analogous to the second section 1404 (FIGS. 14A and 14B). Further, or instead, the ornament 2208 shall be understood to be analogous to the ornament 1408 (FIGS. 14A and 14B) and, in the context of the modular ring system 2200, shall be generally understood as the portion of the modular ring system 2200 dynamically illuminated.

The modular ring system 2200 may further include a light pipe 2260 disposed along a portion of a band 2210 formed by the first section 2202 and the second section 2204 when worn on a digit of the wearer. In certain implementations, the light pipe 2260 may extend from a surface of the band 2210 to the ornament 2208 (e.g., a gem). Continuing with this example, the light pipe 2260 may collect environmental light from along the surface of the band 2210 and direct this light to the ornament 2208 such that illumination of the ornament 2208 is enhanced. While the light pipe 2260 has been described as being arranged to collect environmental light, it shall be appreciated that the light pipe 2260 may be arranged to collect light from a light-emitting diode (e.g., the light-emitting diode 2142 in FIG. 21) and direct such light to the ornament 2208 to illuminate the ornament 2208. Further, or instead, while the light pipe 2260 has been illustrated as a single light pipe, it shall be appreciated that the light pipe 2260 may be any number of light pipes as may be useful for transmitting light toward the ornament 2208 from one or more positions away from the ornament 2208 when the band 2210 is worn on the digit of the wearer.

G. RFID Tagging

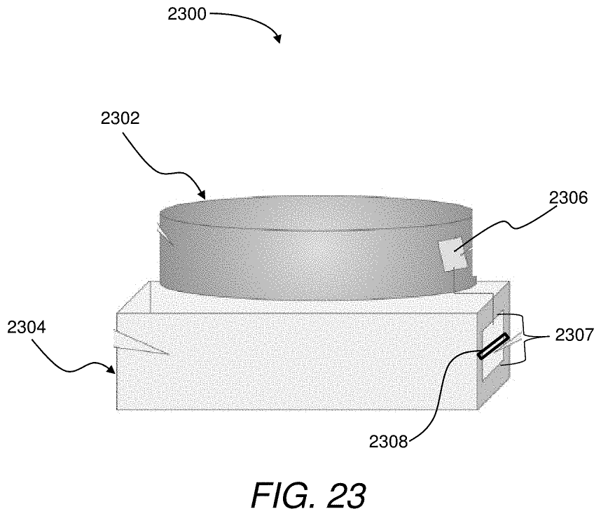

While customization of jewelry has been generally described herein with respect to the appearance of wearable jewelry, customization may additionally or alternatively facilitate improving security and/or authentication of wearable jewelry. For example, referring now to FIGS. 23A-23C, a security system 2300 may include a jewelry piece 2302 and a storage box 2304. The jewelry piece 2302 may include an RFID tag 2306 having an antenna circuit 2307. The storage box 2304 may include a shorting element 2308. With the jewelry piece 2302 properly positioned on the storage box 2304, the security system 2300 is in a “safe state” in which there is no alarm generated. In this state, the shorting element 2308 of the storage box 2304 may short the antenna circuit 2307 of the RFID tag 2306 such that no alarm is generated by the RFID tag 2306. If the jewelry piece 2302 is moved away from the storage box 2304 without authorization, the security system 2300 may enter an “alarm state.” In this state, the antenna circuit 2307 of the RFID tag 2306 may become un-shorted such that the antenna circuit 2307 of the RFID tag 2306 may generate an audible alarm. While the security system 2300 has been described as being activated from the “safe state” to the “alarm state” upon the antenna circuit 2307 of the RFID tag 2306 becoming un-shorted, it shall be appreciated that the security system 2300 may be arranged with the opposite response to un-shorting the antenna circuit 2307 of the RFID tag 2306. Thus, more generally, it shall be understood that a change in the antenna circuit 2307 of the RFID tag 2306 may be the trigger for transitioning the security system 2300 from the “safe state” to the “alarm state” and, thus, activating an audible alarm of the RFID tag 2306.

The above systems, devices, methods, processes, and the like may be realized in hardware, software, or any combination of these suitable for the control, data acquisition, and data processing described herein. This includes realization in one or more microprocessors, microcontrollers, embedded microcontrollers, programmable digital signal processors or other programmable devices or processing circuitry, along with internal and/or external memory. This may also, or instead, include one or more application specific integrated circuits, programmable gate arrays, programmable array logic components, or any other device or devices that may be configured to process electronic signals. It will further be appreciated that a realization of the processes or devices described above may include computer-executable code created using a structured programming language such as C, an object oriented programming language such as C++, or any other high-level or low-level programming language (including assembly languages, hardware description languages, and database programming languages and technologies) that may be stored, compiled or interpreted to run on one of the above devices, as well as heterogeneous combinations of processors, processor architectures, or combinations of different hardware and software. At the same time, processing may be distributed across devices such as the various systems described above, or all of the functionality may be integrated into a dedicated, standalone device. All such permutations and combinations are intended to fall within the scope of the present disclosure.

Embodiments disclosed herein may include computer program products comprising computer-executable code or computer-usable code that, when executing on one or more computing devices, performs any and/or all of the steps of the control systems described above. The code may be stored in a non-transitory fashion in a computer memory, which may be a memory from which the program executes (such as random access memory associated with a processor), or a storage device such as a disk drive, flash memory or any other optical, electromagnetic, magnetic, infrared or other device or combination of devices. In another aspect, any of the control systems described above may be embodied in any suitable transmission or propagation medium carrying computer-executable code and/or any inputs or outputs from same.

The method steps of the implementations described herein are intended to include any suitable method of causing such method steps to be performed, consistent with the patentability of the following claims, unless a different meaning is expressly provided or otherwise clear from the context. So, for example performing the step of X includes any suitable method for causing another party such as a remote user, a remote processing resource (e.g., a server or cloud computer) or a machine to perform the step of X. Similarly, performing steps X, Y and Z may include any method of directing or controlling any combination of such other individuals or resources to perform steps X, Y and Z to obtain the benefit of such steps. Thus, method steps of the implementations described herein are intended to include any suitable method of causing one or more other parties or entities to perform the steps, consistent with the patentability of the following claims, unless a different meaning is expressly provided or otherwise clear from the context. Such parties or entities need not be under the direction or control of any other party or entity, and need not be located within a particular jurisdiction.

It will be appreciated that the methods and systems described above are set forth by way of example and not of limitation. Numerous variations, additions, omissions, and other modifications will be apparent to one of ordinary skill in the art. In addition, the order or presentation of method steps in the description and drawings above is not intended to require this order of performing the recited steps unless a particular order is expressly required or otherwise clear from the context. Thus, while particular embodiments have been shown and described, it will be apparent to those skilled in the art that various changes and modifications in form and details may be made therein without departing from the scope of the disclosure.

1. A method of forming a diamond bulk object, comprising:
heating a crystalline material on a support disposed in a volume defined by a chamber;
introducing into the volume a reactant gas including a hydrogen-containing component and a carbon-containing component;
depositing a plurality of layers of diamond by chemical vapor deposition (CVD) to form at least a portion of the diamond bulk object on the support; and
forming a predetermined color gradient in the plurality of layers of diamond.

2. (canceled)

3. The method of claim 1, further comprising purifying at least one of the hydrogen-containing component or the carbon-containing component of the reactant gas.

4. The method of claim 3, wherein the step of purifying comprises moving the precursor gas through one or more purifiers comprising a palladium membrane, a palladium-copper membrane, a molecular sieve, a pressure-swing adsorber, or a temperature swing adsorber.

5. The method of claim 4, wherein:
the one or more purifiers comprises first and second purifiers; and
the method further comprises providing the purified precursor gas from the first purifier into the second purifier, providing a portion of the purified gas from the second purifier into the volume; and recycling at least a portion of the purified gas from the second purifier into the first purifier.

6. The method of claim 3, wherein the step of purifying electrochemically pumping hydrogen through a proton exchange membrane.

7-14. (canceled)

15. The method of claim 1, further comprising:
forming a getter in a surface region of the diamond bulk object or on a surface the diamond bulk object;
annealing the diamond bulk object to diffuse nitrogen from a central portion of the diamond bulk object to the getter; and
removing the getter from the surface region or from the surface of the diamond bulk object.

16. The method of claim 15, wherein forming the getter in the surface region of the diamond bulk object or on the surface the diamond bulk object comprises in-situ getter doping some of the plurality of layers of diamond which are located in the surface region of the diamond bulk object.

17. The method of claim 15, wherein forming the getter in the surface region of the diamond bulk object or on the surface the diamond bulk object comprises ion implanting getter ions into the surface region of the diamond bulk object.

18. The method of claim 15, wherein forming the getter in the surface region of the diamond bulk object or on the surface the diamond bulk object comprises depositing a layer of the getter on the surface of the diamond bulk object.

19. The method of claim 15, wherein the getter includes nickel, phosphorus, or a combination thereof.

20. The method of claim 1, wherein forming the predetermined color gradient in the plurality of layers of diamond includes irradiating the plurality of layers of diamond with ionizing radiation.

21-29. (canceled)

30. A method of leak testing a chemical vapor deposition (CVD) apparatus, comprising:
placing a dummy substrate in a chamber of the CVD apparatus;
forming a vacuum environment in the chamber;
providing an inert gas into the chamber and subjecting the dummy substrate to a predetermined thermal cycle in the chamber;
detecting if a reaction product of air and a material of the dummy substrate is formed on the dummy substrate; and
providing an alert indicative of a leak in the chamber based on detection of the reaction product on the dummy substrate.

31. The method of claim 30, wherein the dummy substrate comprises a bare silicon wafer, and the reaction product comprises a silicon oxide layer.

32. The method of claim 31, wherein subjecting the dummy substrate to the predetermined thermal cycle includes heating the dummy substrate to a target temperature of greater than about 600° C. and less than about 800° C. for a predetermined period of time.

33. The method of claim 30, wherein the dummy substrate comprises a pyrometric cone or a firing ring.

34. The method of claim 30, wherein the dummy substrate comprises one or more of lithium, magnesium or boron, and the reaction product comprises a lithium nitride, magnesium nitride or boron nitride layer.

35. The method of claim 30, further comprising pressurizing an environment outside of the chamber with an inert gas in response to providing the alert indicative of the leak.

36. A method of calibrating a temperature of a chemical vapor deposition (CVD) apparatus, comprising:
placing a dummy substrate in a chamber of the CVD apparatus;
forming a vacuum environment in the chamber;
providing a reactant into the chamber and subjecting the dummy substrate to a predetermined temperature in the chamber;
forming a reaction product layer of the reactant and a material of the dummy substrate on the dummy substrate;
determining a thickness of the reaction product layer; and
determining if the temperature of the CVD apparatus is properly calibrated based on comparing the determined thickness of the reaction product layer to a stored thickness value for the predetermined temperature.

37. The method of claim 36, wherein the dummy substrate comprises a bare silicon wafer, the reactant comprises an oxygen containing gas and the reaction product layer comprises a silicon oxide layer.

38. The method of claim 36, wherein the dummy substrate comprises one or more of lithium, magnesium or boron, the reactant comprises a nitrogen containing gas and the reaction product comprises a lithium nitride, magnesium nitride or boron nitride layer.

39-80. (canceled)
